(19) United States
(12) Patent Application Publication
(10) Pub. No.: US 2025/0293714 A1
(43) Pub. Date: Sep. 18, 2025

(54) Duplexer Circuit Arrangement

(71) Applicant: RF 360 Singapore Pte. Ltd., Republic Plaza (SG)

(72) Inventors: Marc Esquius Morote, Munich (DE); Juha Sakari Ella, Turku (FI); Edgar Konrad Schmidhammer, Stein an der Traun (DE)

(21) Appl. No.: 18/602,929

(22) Filed: Mar. 12, 2024

(51) Int. Cl. H04B 1/00; H03F 3/24; H04B 1/04

(52) U.S. Cl. CPC H04B 1/0057; H03F 3/245; H04B 1/0458; H03F 2200/451; H04B 2001/0408

(57) ABSTRACT

An apparatus is disclosed for a duplexer circuit arrangement. In example aspects, the apparatus includes at least one duplexer circuit arrangement having a first port, a second port, and a third port. The duplexer circuit arrangement includes a first duplexer, a second duplexer, a first hybrid, and a second hybrid. The first hybrid is coupled between the first port and the first duplexer and between the first port and the second duplexer. The second hybrid is coupled between the second port and the second duplexer and between the second port and the first duplexer. The duplexer circuit arrangement also includes a splitter and phase shifter circuit coupled between the third port and the first and second duplexers.

### TECHNICAL FIELD

This disclosure relates generally to signal communication or signal processing using an electronic device and, more specifically, to employing a circuit arrangement for signal duplexing.

### BACKGROUND

Electronic devices include traditional computing devices such as desktop computers, notebook computers, smartphones, wearable devices like a smartwatch, internet servers, and so forth. Electronic devices also include other types of computing devices such as personal voice assistants (e.g., smart speakers), wireless access points or routers, thermostats and other automated controllers, robotics, automotive electronics, devices embedded in other machines like refrigerators and industrial tools, Internet of Things (IoT) devices, medical devices, and so forth. These various electronic devices provide services relating to productivity, communication, social interaction, security, health and safety, remote management, entertainment, transportation, artificial intelligence, and information dissemination. Thus, electronic devices play crucial roles in modern society.

Many of the services provided by electronic devices in today's interconnected world depend at least partly on electronic communications. Electronic communications can include, for example, those exchanged between two or more electronic devices using wireless or wired signals that are transmitted over one or more networks, such as the Internet, a Wi-Fi® network, or a cellular network. Electronic communications can therefore include wireless or wired transmissions and receptions. To transmit and receive communications, an electronic device can use a transceiver, such as a wireless transceiver that is designed for wireless communications.

Electronic communications can therefore be realized by propagating signals between two wireless transceivers at two different electronic devices. For example, using a wireless transmitter, a smartphone can transmit a wireless signal to a base station over the air as part of an uplink communication to support mobile services. Using a wireless receiver, the smartphone can receive a wireless signal that is transmitted from the base station via the air medium as part of a downlink communication to enable mobile services.

With a smartphone, mobile services can include making voice and video calls, participating in social media interactions, sending or receiving messages, watching movies, sharing videos, and performing searches. Other mobile services can include using map information or navigational instructions, finding friends, engaging in location-based services generally, transferring money, obtaining another service like a car ride, and so forth.

Many of these mobile services depend at least partly on the transmission or reception of wireless signals between two or more electronic devices. Consequently, researchers, electrical engineers, and designers of electronic devices strive to develop wireless transceivers that can use wireless signals effectively to provide these and other mobile services.

### SUMMARY

A wireless transceiver or a radio-frequency (RF) front-end can include a three-port duplexer that enables bi-directional signal propagation over a single path or via one resource, such as an antenna. For frequency-based duplexing, a relatively simple duplexer may include two filters that target different frequencies. To increase isolation between two propagating signals or lower the insertion loss experienced by the signals, an extended duplexer circuit can be deployed. An extended duplexer circuit may include two duplexers and three hybrids, as well as a load for each hybrid or hybrid coupler. Although an extended duplexer has superior isolation as compared to a simple duplexer, the extended duplexer results in a large and thus expensive apparatus. To reduce the size, this document describes example implementations of a duplexer circuit arrangement that can eliminate at least one hybrid and corresponding load. Instead, at one or more of three ports of a duplexer circuit arrangement, a splitter and phase shifter circuit is employed. The resulting circuitry is simpler and occupies less space. The splitter and phase shifter circuit can be realized using, for instance, two electrical branches. Each branch may include a respective phase shifter or a respective inductor or capacitor. Other described implementations increase a level of integration, increase signal isolation, or further reduce the size of a hybrid. For example, a load can be realized as part of an acoustic chip, or capacitors can be coupled between two selected hybrid ports of at least one hybrid. These and other example implementations are described herein.

In an example aspect, an apparatus including at least one duplexer circuit arrangement is disclosed. The duplexer circuit arrangement includes a first port, a second port, a third port, a first duplexer, and a second duplexer. The duplexer circuit arrangement also includes a first hybrid coupled between the first port and the first duplexer and between the first port and the second duplexer. The duplexer circuit arrangement additionally includes a second hybrid coupled between the second port and the second duplexer and between the second port and the first duplexer. The duplexer circuit arrangement further includes a splitter and phase shifter circuit coupled between the third port and the first and second duplexers.

In an example aspect, an apparatus including at least one duplexer circuit arrangement is disclosed. The duplexer circuit arrangement includes a first port, a second port, a third port, a first duplexer, and a second duplexer. The duplexer circuit arrangement also includes first means for coupling the first port to the first duplexer and the second duplexer. The duplexer circuit arrangement additionally includes second means for coupling the second port to the second duplexer and the first duplexer. The duplexer circuit arrangement further includes means for splitting and phase shifting at least one signal propagating between the third port and the first and second means for coupling.

In an example aspect, a method of processing at least one signal with at least two duplexers is disclosed. The method includes splitting a reception signal into a first reception signal component and a second reception signal component. The method also includes shifting a phase of the first reception signal component responsive to propagating the first reception signal component along a first path to produce a first phase-shifted reception signal component. The method additionally includes filtering the first phase-shifted reception signal component using a first duplexer to produce a first filtered reception signal component. The method also includes shifting a phase of the second reception signal component responsive to propagating the second reception signal component along a second path to produce a second phase-shifted reception signal component. The method additionally includes filtering the second phase-shifted reception signal component using a second duplexer to produce a second filtered reception signal component. The method further includes joining the first filtered reception signal component and the second filtered reception signal component to produce a combined reception signal.

In an example aspect, an apparatus including a duplexer circuit arrangement is disclosed. The duplexer circuit arrangement includes a first port, a second port, a third port, a first duplexer, and a second duplexer. The duplexer circuit arrangement also includes a first hybrid and a second hybrid. The first hybrid is coupled between the first port and the first duplexer and between the first port and the second duplexer. The second hybrid is coupled between the second port and the second duplexer and between the second port and the first duplexer. The duplexer circuit arrangement additionally includes a first path coupled between the first duplexer and the third port, with the first path including at least one capacitor. The duplexer circuit arrangement further includes a second path coupled between the second duplexer and the third port, with the second path including at least one inductor.

### BRIEF DESCRIPTION OF DRAWINGS

FIG. 1 illustrates an environment with an example electronic device that has a wireless interface device, which includes at least one example duplexer circuit arrangement.

FIG. 2-1 is a schematic diagram illustrating an example radio-frequency (RF) front-end and an example transceiver that can each include at least one duplexer circuit arrangement.

FIG. 2-2 is a schematic diagram illustrating an example RF front-end (RFFE) that can include one or more duplexer circuit arrangements coupled between at least one antenna and one or more amplifiers for a transmit chain and a receive chain.

FIGS. 3-1 to 3-5 illustrate example approaches to implementing a smaller or simpler duplexer circuit arrangement using at least one splitter and phase shifter circuit.

FIGS. 4-1 to 4-3 illustrate example approaches to reducing the size of a hybrid, such as one that is part of duplexer circuit arrangement.

FIGS. 5-1 and 5-2 illustrate example approaches to increasing isolation with a duplexer circuit arrangement using at least one hybrid.

FIG. 6 illustrates example approaches to increasing isolation with a duplexer circuit arrangement using at least one load.

FIG. 7 is a flow diagram illustrating an example process for operating at least one duplexer circuit arrangement.

### DETAILED DESCRIPTION

### Introduction and Overview

To facilitate transmission and reception of wireless signals, an electronic device can use a wireless interface device that includes a wireless transceiver and/or a radio-frequency (RF) front-end. Electronic devices communicate with wireless signals using electromagnetic (EM) signals at various frequencies that exist on a portion of the EM spectrum. These wireless signals may travel between two electronic devices at a particular frequency, such as a kilohertz (kHz) frequency, a megahertz (MHz) frequency, or a gigahertz (GHz) frequency. The EM spectrum is, however, a finite resource that limits how many signals can be simultaneously communicated in any given spatial area without creating interference. To enable a greater number of simultaneous communications using EM signaling, the finite EM spectrum can be shared among electronic devices. The EM spectrum can be shared using, for instance, frequency division multiplexing (FDM) and/or time division multiplexing (TDM) techniques.

Techniques for FDM or TDM can entail separating the EM spectrum into different frequency bands and constraining communications to occur within an assigned frequency band or during an allocated time period. Signals in different frequency bands can be communicated at the same time in a same area without significantly interfering with each other. To transmit a signal within a target frequency band, a transmitter can apply a filter to the signal. The filter passes the frequencies of the target frequency band and suppresses (e.g., attenuates, reduces, or blocks) other frequencies. Thus, filters can support FDM and/or TDM techniques to facilitate efficient sharing of the EM spectrum. Further, filters can enable a resource of a given device, such as an antenna, to be shared between two or more signals simultaneously.

A wireless transceiver or an RF front-end of an electronic device can include a filter that passes the desired frequencies of a signal within a target frequency band but suppresses the undesired ones outside of the band. Some filters use combinations of inductors and capacitors to suppress frequencies. Other filters use acoustic resonators, like a bulk acoustic wave (BAW) resonator or a surface acoustic wave (SAW) resonator, to filter frequencies using a piezoelectric material. Each acoustic resonator may be associated with a resonant frequency that corresponds to which frequency or frequencies can be passed or suppressed using the acoustic resonator. Filters can also include one or more transformers to act as a balun to process balanced and unbalanced signals.

As one use of a filter, a wireless transceiver or an RF front-end can include a duplexer that permits bidirectional signal propagation over a single path or component. This enables a resource, such an antenna, to be used for transmission and reception operations, including at the same time in some scenarios. A duplexer can include, for instance, two filters that pass the two desired frequencies of two signals (e.g., a transmit signal and a receive signal) but suppress the undesired ones. A filter of a duplexer may include one or more acoustic resonators that can filter frequencies of RF signals using sound waves. Generally, duplexer filters can use, for example, transformers, acoustic resonators, capacitors, and/or inductors to achieve a desired filter response. Further, some electronic devices have multiple instances of such duplexers to enable communications across different frequency bands or the sharing of multiple resources. Consequently, an electronic device can include numerous instances of any of these components.

To increase a number of simultaneous communications that can be made in a given space or to increase communication bandwidth, the frequencies used by electronic devices can be increased. Expanding from using MHz frequencies to using MHz and GHz frequencies, for instance, can increase bandwidth or opportunities for simultaneous communications. For example, some of the frequency bands for upcoming 3rd Generation Partnership Project (3GPP) 6^{th} Generation (6G) systems will be higher than those of the current 5^{th} Generation (5G) systems. Using these higher frequencies, however, can be problematic.

Consider the FR3 frequency region offering multiple frequency bands for 6G electronic devices. Efficiently using the new 6G frequency bands within FR3 will entail deploying low-loss and high-isolation duplexers (DPX). In some approaches, lower loss can be achieved by relaxing the rejection level of certain specifications. Some of those rejections might be achievable by using components besides acoustic resonators, such as inductors and capacitors. However, a high isolation between transmit (Tx) and receive (Rx) paths involves high-order acoustic filters. At higher frequencies (e.g., >7 GHZ), both ohmic and acoustic losses are appreciably high, and the insertion loss (IL) degrades rapidly when adding filter stages. Using external elements like a circulator to increase the isolation adds even more losses to the system.

In other approaches, some of these issues can be addressed at least partially using an extended duplexer circuit. Relative to a simple duplexer, an extended duplexer can increase the isolation between Tx and Rx ports and can make the performance more robust in cases of antenna mismatch. The extended duplexer, however, is appreciably larger and more complicated than a simple duplexer. Instead of one duplexer, an extended duplexer can include two duplexers, three hybrids or hybrid couplers, and three respective loads. Further, the three hybrids of the extended duplexer create additional losses.

These traits of an extended duplexer circuit may be more impactful at higher frequencies, such as those for the upcoming FR3 6G bands (different frequency ranges between 7-24 GHZ). Integrating these various components at higher frequencies is particularly challenging. First, there are currently no hybrids in a surface-mount device (SMD) package for this frequency range. Regardless, if such hybrids were available, the parasitics of the interconnects, laminate encapsulation, and so forth would likely degrade the signal isolation too much. Similar frequency-based hurdles exist for the loads (e.g., 50 Ohm resistors) for the hybrids. Although such loads are available as SMDs that operate up to the mmWave range, the interconnects and laminate layout would also appreciably degrade the isolation for an extended duplexer circuit.

Another trait that can be impactful is the size and complexity of an extended duplexer circuit. In some 5G and many 6G architectures, a large array of antenna elements, numerous amplifiers, and multiple filters/duplexers are or will be employed. Modifying or integrating the components of an extended duplexer circuit while still providing at least comparable performance would facilitate incorporating more duplexer circuits in a given device, especially for those that are resource constrained due to size (e.g., a mobile device). A smaller or simpler duplexer circuit that is highly integrated can expand the scenarios in which a duplexer circuit can be successfully deployed. Examples of such scenarios include devices that support 6G technologies, such as Sub-Band Full Duplex (SBFD) applications.

This document describes example approaches that can at least ameliorate these issues to enable smaller duplexing components to be manufactured. In some implementations, an example duplexer circuit arrangement can be smaller by including no more than two hybrids. Instead of a third hybrid, the duplexer circuit arrangement can include a splitter and phase shifter circuit. This results in a duplexer circuit arrangement with reduced complexity, size, and losses. In some cases, the splitter and phase shifter circuit is coupled between an antenna and two duplexers of the duplexer circuit arrangement.

In other example implementations, a hybrid of an example duplexer circuit arrangement can be constructed using two coupled lines. To reduce the area occupied by the hybrid, the lengths of these two coupled lines can be shortened. The shorter lines may alter the power routing along two or more paths. However, the power split can be better balanced by coupling a first capacitor across two hybrid ports as described herein. Adding a second capacitor across two different hybrid ports can compensate for a phase difference that might otherwise be produced by the first capacitor.

In other example implementations, the isolation between two signals propagating through an example duplexer circuit arrangement can be increased by adjusting a hybrid. If the hybrid is constructed with two coupled lines, the length or width of the coupled lines may be adjusted to increase the isolation. This adjustment may introduce a phase offset, however. Additionally, respective capacitors can be coupled across pairs of hybrid ports of the adjusted hybrid as described herein. If the hybrid is constructed with two coupled lines, the capacitors can be coupled across pairs of hybrid ports from different coupled lines to further increase the signal isolation. The same phase offset resulting from the length or width adjustment of the coupled lines may be created or maintained at another hybrid of the duplexer circuit arrangement to create a global phase offset. The global phase offset can thus be consistent across the duplexer circuit arrangement. As long as the relative phase offset remains approximately ninety degrees (90°), performance need not be adversely impacted by the global phase offset.

In other example implementations, the isolation between two signals propagating through an example duplexer circuit arrangement can also be increased by integrating a load for a hybrid in an acoustic chip that includes an acoustic filter of a duplexer. To enable a small size for the load, a resistive load can be formed using a meandering line. This meandered line or the interconnects thereof may tend to introduce inductive parasitics. However, the inductive effects can be counteracted by integrating a capacitor in parallel with the resistor.

These various implementations may be realized separately or in any combination. The example implementations can simplify or reduce the size of a duplexer circuit arrangement, improve the isolation between ports or the signals that propagate through the ports, increase a level of integration, or some combination thereof. These and other implementations are described herein.

### DESCRIPTION EXAMPLES

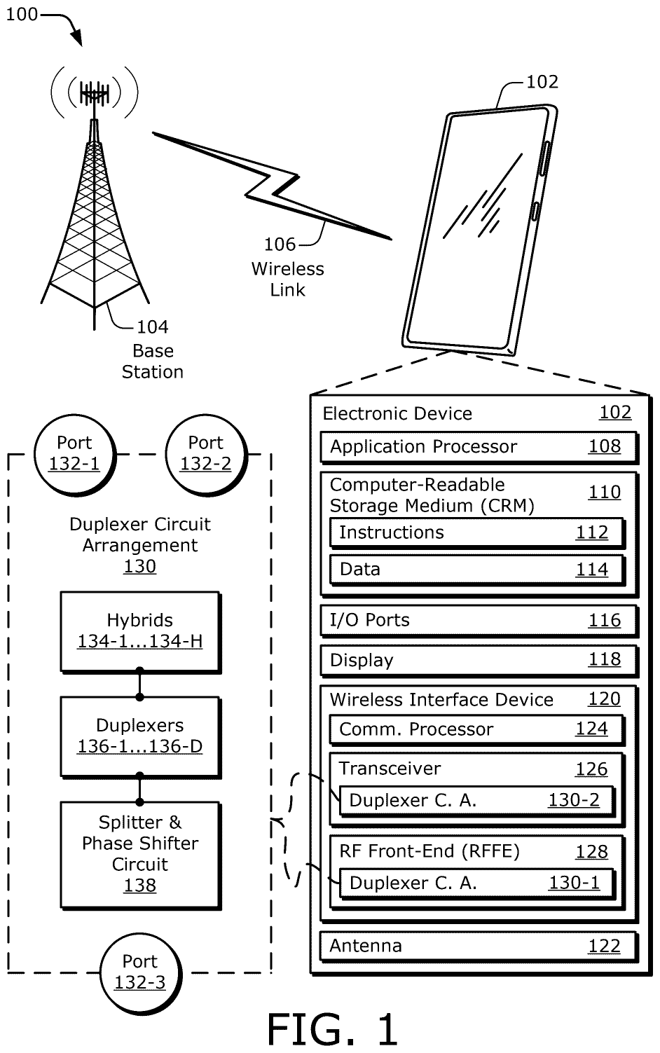

FIG. 1 illustrates an example environment 100 with an electronic device 102 that has a wireless interface device 120, which includes at least one example duplexer circuit arrangement 130 (Duplexer C. A. 130). This document describes example implementations of a duplexer circuit arrangement 130, which may be part of a transceiver, a radio-frequency front-end (RFFE), and so forth of an apparatus. In the environment 100, the example electronic device 102 communicates with a base station 104 through a wireless link 106. In FIG. 1, the electronic device 102 is depicted as a smartphone. The electronic device 102, however, may be implemented as any suitable computing or other electronic device. Examples of an apparatus that can be realized as an electronic device 102 include a cellular base station, broadband router, access point, cellular or mobile phone, gaming device, navigation device, media device, laptop computer, desktop computer, tablet computer, server computer, network-attached storage (NAS) device, smart appliance, vehicle-based communication system, Internet of Things (IoT) device, sensor or security device, asset tracker, fitness management device, wearable device such as intelligent glasses or smartwatch, wireless power device (transmitter or receiver), medical device, and so forth.

The base station 104 communicates with the electronic device 102 via the wireless link 106, which may be implemented as any suitable type of wireless link that carries a communication signal. Although depicted as a base station tower of a cellular radio network, the base station 104 may represent or be implemented as another device, such as a satellite, terrestrial broadcast tower, access point, peer-to-peer device, mesh network node, fiber optic line interface, another electronic device as described above generally, and so forth. Hence, the wireless link 106 can extend between the electronic device 102 and the base station 104 in any of various manners.

The wireless link 106 can include a downlink of data or control information communicated from the base station 104 to the electronic device 102. The wireless link 106 can also include an uplink of other data or control information communicated from the electronic device 102 to the base station 104. The wireless link 106 may be implemented using any suitable wireless communication protocol or standard. Examples of such protocols and standards include a 3^{rd} Generation Partnership Project (3GPP) Long-Term Evolution (LTE) standard, such as a 4^{th} Generation (4G), a 5^{th} Generation (5G), or a 6^{th} Generation (6G) cellular standard; an IEEE 802.11 standard, such as 802.11g, ac, ax, ad, aj, or ay standard (e.g., Wi-Fi® 6 or WiGig®); an IEEE 802.16 standard (e.g., WiMAX®); a Bluetooth® standard; an ultra-wideband (UWB) standard (e.g., IEEE 802.15.4); and so forth. In some implementations, the wireless link 106 may provide power wirelessly, and the electronic device 102 or the base station 104 may comprise a power source.

As shown for some implementations, the electronic device 102 can include at least one application processor 108 and at least one computer-readable storage medium 110 (CRM 110). The application processor 108 may include any type of processor, such as a central processing unit (CPU) or a multi-core processor, that is configured to execute processor-executable instructions (e.g., code) stored by the CRM 110. The CRM 110 may include any suitable type of data storage media, such as volatile memory (e.g., random-access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the electronic device 102, and thus the CRM 110 does not include transitory propagating signals or carrier waves.

The electronic device 102 may also include one or more input/output ports 116 (I/O ports 116) and at least one display 118. The I/O ports 116 enable data exchanges or interaction with other devices, networks, or users. The I/O ports 116 may include serial ports (e.g., universal serial bus (USB®) ports), parallel ports, ethernet ports, audio ports, infrared (IR) ports, cameras or other sensor ports, and so forth. The display 118 can be realized as a display screen or a projection that presents graphical images provided by other components of the electronic device 102, such as a user interface (UI) associated with an operating system, program, or application. Alternatively or additionally, the display 118 may be implemented as a display port or virtual interface through which graphical content of the electronic device 102 is communicated or presented.

The electronic device 102 further includes at least one wireless interface device 120 and at least one antenna 122. The example wireless interface device 120 provides connectivity to respective networks and peer devices via a wireless link, which may be configured similarly to or differently from the wireless link 106. The wireless interface device 120 may facilitate communication over any suitable type of wireless network, such as a wireless local area network (LAN) (WLAN), wireless personal-area-network (PAN) (WPAN), peer-to-peer (P2P) network, mesh network, cellular network, wireless wide-area-network (WAN) (WWAN), and/or navigational network (e.g., the Global Positioning System (GPS) of North America or another Satellite Positioning System (SPS) or Global Navigation Satellite System (GNSS)). In the context of the example environment 100, the electronic device 102 can communicate various data and control information bidirectionally with the base station 104 via the wireless interface device 120. The electronic device 102 may, however, communicate directly with other peer devices, an alternative wireless network, and the like. Also, as described above, an electronic device 102 may alternatively be implemented as a base station 104 or another apparatus as set forth herein.

As shown, the wireless interface device 120 can include at least one communication processor 124, at least one transceiver 126, and at least one radio-frequency front-end 128 (RFFE 128). These components process data information, control information, and signals associated with communicating information for the electronic device 102 via the antenna 122. The communication processor 124 may be implemented as at least part of a system-on-chip (SoC), as a modem processor, or as a baseband radio processor (BBP) that enables a digital communication interface for data, voice, messaging, or other applications of the electronic device 102. The communication processor 124 can include a digital signal processor (DSP) or one or more signal-processing blocks (not shown) for encoding and modulating data for transmission and for demodulating and decoding received data. Additionally, the communication processor 124 may also manage (e.g., control or configure) aspects or operation of the transceiver 126, the RF front-end 128, and other components of the wireless interface device 120 to implement various communication protocols or communication techniques.

In some cases, the application processor 108 and the communication processor 124 can be combined into one module or integrated circuit (IC), such as an SoC. Regardless, the application processor 108, the communication processor 124, or a processor generally can be operatively coupled to one or more other components, such as the CRM 110 or the display 118, to enable control of, or other interaction with, the various components of the electronic device 102. For example, at least one processor 108 or 124 can present one or more graphical images on a display screen implementation of the display 118 based on one or more wireless signals communicated (e.g., transmitted or received) via the at least one antenna 122 using components of the wireless interface device 120. Further, the application processor 108 or the communication processor 124, including a combination thereof, can be realized using digital circuitry that implements logic or functionality that is described herein. Additionally, the communication processor 124 may also include or be associated with a memory (not separately depicted) to store data and processor-executable instructions (e.g., code), such as the same CRM 110 or another CRM 110.

As shown, the wireless interface device 120 can include at least one duplexer circuit arrangement 130 (Duplexer C. A. 130), which is described below. More specifically, the transceiver 126 can include at least one duplexer circuit arrangement 130-2, or the RF front-end 128 can include at least one duplexer circuit arrangement 130-1 (including both components can have at least one duplexer circuit arrangement 130 in accordance with an optional but permitted inclusive-or interpretation of the word “or”). The transceiver 126 can also include circuitry and logic for filtering, switching, amplification, channelization, frequency translation, and so forth. Frequency translation functionality may include an up-conversion or a down-conversion of frequency that is performed through a single conversion operation (e.g., with a direct-conversion architecture) or through multiple conversion operations (e.g., with a superheterodyne architecture). Generally, the transceiver 126 can include filters, switches, amplifiers, mixers, and so forth for routing and conditioning signals that are transmitted or received via the antenna 122.

In addition to the duplexer circuit arrangement 130-2, the transceiver 126 can include an analog-to-digital converter (ADC) or a digital-to-analog converter (DAC) (not shown in FIG. 1). In operation, an ADC can convert analog signals to digital signals, and a DAC can convert digital signals to analog signals. Generally, an ADC or a DAC can be implemented as part of the communication processor 124, as part of the transceiver 126, or separately from both (e.g., as another part of an SoC or as part of the application processor 108).

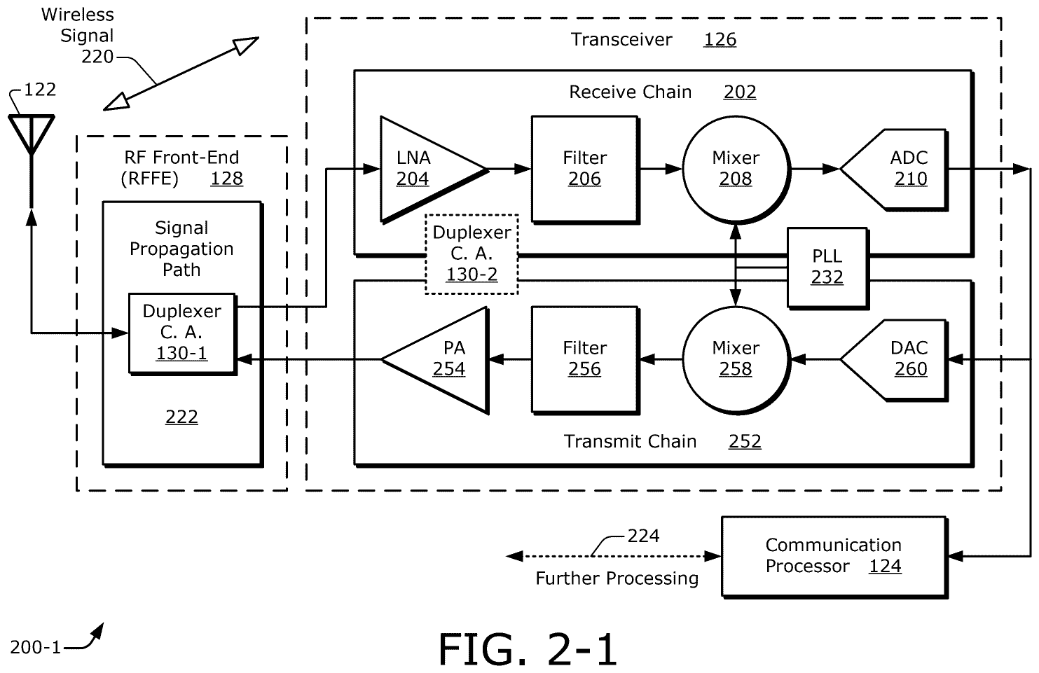

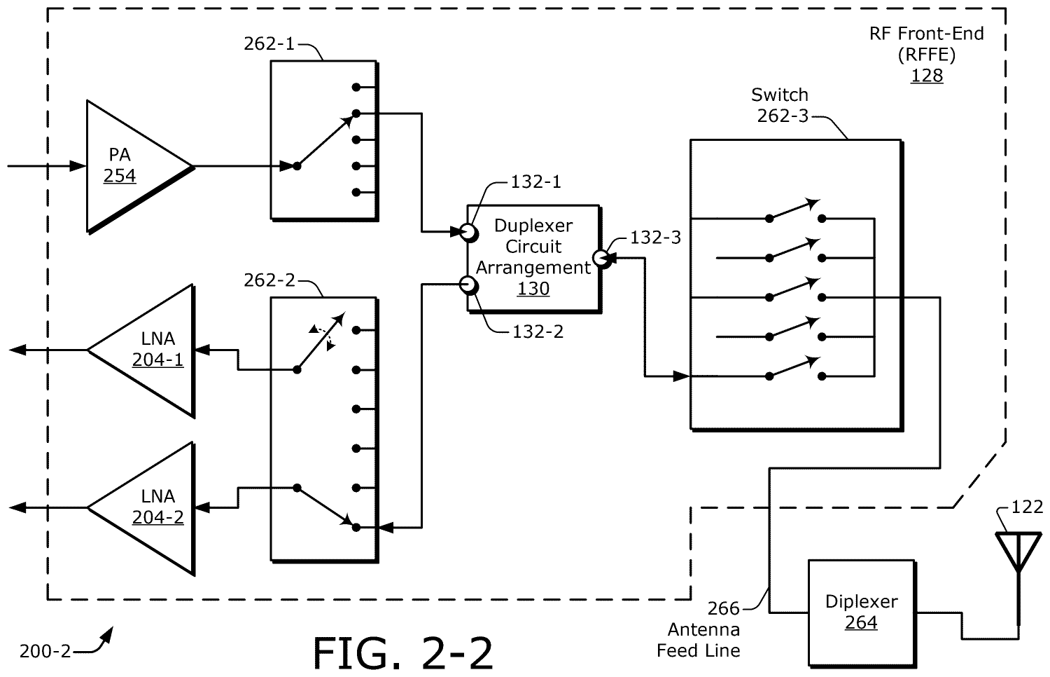

The components or circuitry of the transceiver 126 can be implemented in any suitable fashion, such as with combined transceiver logic or separately as respective transmitter and receiver entities. In some cases, the transceiver 126 is implemented with multiple or different sections to implement respective transmitting and receiving operations (e.g., with separate transmit and receive chains as depicted in FIG. 2). Although not shown in FIG. 1, the transceiver 126 may also include logic to perform in-phase/quadrature (I/Q) operations, such as synthesis, phase correction, modulation, demodulation, and the like.

The RF front-end 128 can include one or more duplexing components—such as the duplexer circuit arrangement 130-1—multiple filters, multiple switches, or one or more amplifiers for conditioning signals received via the antenna 122 or for conditioning signals to be transmitted via the antenna 122. The RF front-end 128 may also include a phase shifter (PS), peak detector, power meter, gain control block, antenna tuning circuit, N-plexer, balun, and the like. Configurable components of the RF front-end 128, such as some amplifiers, an automatic gain controller (AGC), or an adjustable/switchable filter, may be controlled by the communication processor 124 to implement communications in various modes, with different frequency bands and/or carrier aggregation (CA), or using beamforming. In some implementations, the antenna 122 is implemented as at least one antenna array that includes multiple antenna elements. Thus, as used herein, an “antenna” can refer to at least one discrete or independent antenna, to at least one antenna array that includes multiple antenna elements, or to a portion of an antenna array (e.g., an antenna element), depending on context or implementation.

In FIG. 1, an example duplexer circuit arrangement 130 is depicted as being part of a transceiver 126 as a duplexer circuit arrangement 130-2, as being part of an RF front-end 128 as a duplexer circuit arrangement 130-1, and so forth. Described implementations of a duplexer circuit arrangement 130 can, however, additionally or alternatively be employed in other portions of the wireless interface device 120 or in other portions of the electronic device 102 generally. As set forth above, a duplexer circuit arrangement 130 can be included in an electronic device other than a cell phone, such as a base station 104. With a base station (or a mobile phone) environment, a duplexing component of, e.g., an RF or intermediate frequency (IF) section of a wireless interface device 120 and/or an RF front-end 128 may include a duplexer circuit arrangement 130 as described herein. Other electronic device apparatuses that can employ a duplexer circuit arrangement 130 include a laptop, communication hardware of a vehicle, a wireless access point, and so forth as described herein.

In example implementations, the duplexer circuit arrangement 130 can include at least one port 132, at least one hybrid 134, at least one duplexer 136, and at least one splitter and phase shifter circuit 138. Thus, a duplexer circuit arrangement 130 can include multiple hybrids 134-1 . . . 134-H, with “H” representing an integer of one or greater. Each hybrid 134 can be implemented, for example, as a hybrid coupler, such as a quadrature (or) 90° hybrid coupler. Also, a duplexer circuit arrangement 130 can include multiple duplexers 136-1 . . . 136-D, with “D” representing an integer of one or greater. Further, a duplexer circuit arrangement 130 can include multiple splitter and phase shifter circuits although only one such splitter and phase shifter circuit 138 is shown in FIG. 1.

As illustrated, the duplexer circuit arrangement 130 includes multiples ports, such as a first port 132-1, a second port 132-2, and a third port 132-3. A duplexer circuit arrangement 130 can, however, include more or fewer ports. In some cases, one port can correspond to or operate as a transmission port for transmit or transmission signals, and another port can correspond to or operate as a reception port for receive or reception signals. Yet another port can correspond to or operate as an antenna port for transmission signals and reception signals. Although certain quantities of one or more ports, one or more hybrids, one or more duplexers, or at least one splitter and phase shifter circuit are explicitly shown, a duplexer circuit arrangement 130 may include more or fewer of any of such components, as well as other components that are not shown.

Example implementations of a duplexer circuit arrangement 130 are described below with reference to FIGS. 3-1 to 6. Next, however, this document describes example implementations of a transceiver and an RF front-end with reference to FIGS. 2-1 and 2-2. At least one duplexer circuit arrangement 130 can be employed in a transceiver or an RF front-end.

FIG. 2-1 is a schematic diagram 200-1 illustrating an example RF front-end 128 and an example transceiver 126 that can each include at least one duplexer circuit arrangement 130. FIG. 2-1 also depicts an antenna 122 and a communication processor 124. The communication processor 124 communicates one or more data signals to other components, such as the application processor 108 of FIG. 1, for further processing at 224 (e.g., for processing at an application level). As shown, the circuitry 200-1 can include a duplexer circuit arrangement 130-1 or a duplexer circuit arrangement 130-2, including one or two of such duplexer circuit arrangements. The circuitry 200-1, however, may include a different quantity of duplexer circuit arrangements (e.g., more or fewer), may include duplexer circuit arrangements that are coupled together differently, may include duplexer circuit arrangements in different locations, may include duplexer circuit arrangements that are implemented as a quadplexer or a part thereof (e.g., a quadplexer circuit arrangement), and so forth.

As illustrated from left to right, in example implementations, the antenna 122 is coupled to the RF front-end 128, and the RF front-end 128 is coupled to the transceiver 126. The transceiver 126 is coupled to the communication processor 124. The example RF front-end 128 includes at least one signal propagation path 222. The at least one signal propagation path 222 can include at least one duplexer circuit arrangement 130, such as the duplexer circuit arrangement 130-1. The example transceiver 126 includes at least one receive chain 202 (or receive path 202) and at least one transmit chain 252 (or transmit path 252). Although only one RF front-end 128, one transceiver 126, and one communication processor 124 are shown at the circuitry 200-1, an electronic device 102, or a wireless interface device 120 thereof, can include multiple instances of any or all such components. Also, although only certain components are explicitly depicted in FIG. 2 and are shown coupled together in a particular manner, the transceiver 126 or the RF front-end 128 may include other non-illustrated components (e.g., switches or diplexers), more or fewer components, differently coupled arrangements of components, and so forth.

In some implementations, the RF front-end 128 couples the antenna 122 to the transceiver 126 via the signal propagation path 222. In operation, the signal propagation path 222 carries a signal between the antenna 122 and the transceiver 126. During or as part of the signal propagation, the signal propagation path 222 conditions the propagating signal, such as with the duplexer circuit arrangement 130-1. This enables the RF front-end 128 to couple a wireless signal 220 from the antenna 122 to the transceiver 126 as part of a reception operation. The RF front-end 128 also enables a transmission signal to be coupled from the transceiver 126 to the antenna 122 as part of a transmission operation to emanate a wireless signal 220. Although not explicitly shown in FIG. 2-1, an RF front-end 128, or a signal propagation path 222 thereof, may include one or more other components, such as another duplexer circuit arrangement, a filter, an amplifier (e.g., a power amplifier or a low-noise amplifier), an N-plexer, a phase shifter, a diplexer, one or more switches, and so forth.

In some implementations, the transceiver 126 can include at least one receive chain 202, at least one transmit chain 252, or at least one receive chain 202 and at least one transmit chain 252. From left to right, the receive chain 202 can include a low noise amplifier 204 (LNA 204), a filter 206, a mixer 208 for frequency down conversion, and an ADC 210. The transmit chain 252 can include a power amplifier 254 (PA 254), a filter 256, a mixer 258 for frequency up-conversion, and a DAC 260. However, the receive chain 202 or the transmit chain 252 can include other components—for example, at least one duplexer circuit arrangement 130 (e.g., the duplexer circuit arrangement 130-2), additional amplifiers or filters, multiple mixers, one or more buffers, or at least one local oscillator—that are electrically or electromagnetically disposed anywhere along the depicted receive and transmit chains.

The receive chain 202 is coupled between the signal propagation path 222 of the RF front-end 128 and the communication processor 124—e.g., via the low-noise amplifier 204 and the ADC 210, respectively. The transmit chain 252 is coupled between the signal propagation path 222 and the communication processor 124—e.g., via the power amplifier 254 and the DAC 260, respectively. The transceiver 126 can also include at least one phase-locked loop 232 (PLL 232) that is coupled to the mixer 208 or the mixer 258. For example, the transceiver 126 can include one PLL 232 for each transmit/receive chain pair, one PLL 232 per transmit chain and one PLL 232 per receive chain, multiple PLLs 232 per chain, and so forth.

As shown along a signal propagation direction for certain example implementations of the receive chain 202, the antenna 122 is coupled to the low noise amplifier 204 via the signal propagation path 222 and the duplexer circuit arrangement 130-1 thereof. The low-noise amplifier 204 is coupled to the filter 206. The filter 206 is coupled to the mixer 208, and the mixer 208 is coupled to the ADC 210. The ADC 210 is in turn coupled to the communication processor 124. As shown along a signal propagation direction for certain example implementations of the transmit chain 252, the communication processor 124 is coupled to the DAC 260, and the DAC 260 is coupled to the mixer 258. The mixer 258 is coupled to the filter 256, and the filter 256 is coupled to the power amplifier 254. The power amplifier 254 is coupled to the antenna 122 via the signal propagation path 222 using the duplexer circuit arrangement 130-1 thereof. Although only one receive chain 202 and one transmit chain 252 are explicitly shown, an electronic device 102, or a transceiver 126 thereof, can include multiple instances of either or both components. Although the ADC 210 and the DAC 260 are illustrated as being separately coupled to the communication processor 124, they may share a bus or other means for communicating with the processor 124. Further, the ADC 210 or the DAC 260 may be part of the communication processor 124 or separate from the transceiver 126 and the communication processor 124.

As part of an example signal-receiving operation, the duplexer circuit arrangement 130-1 of the signal propagation path 222 filters a received signal and forwards the filtered signal to the low-noise amplifier 204. The low-noise amplifier 204 accepts the filtered signal from the RF front-end 128 and provides an amplified signal to the filter 206 based on the accepted signal. The filter 206 filters the amplified signal and provides another filtered signal to the mixer 208. The mixer 208 performs a frequency conversion operation on the other filtered signal to down-convert from one frequency to a lower frequency (e.g., from a radio frequency (RF) to an intermediate frequency (IF) or from RF or IF to a baseband frequency (BBF)). The at least one mixer 208 can perform the frequency down-conversion in a single conversion step or through multiple conversion steps using at least one PLL 232. The mixer 208 can provide a down-converted signal to the ADC 210 for conversion and forwarding to the communication processor 124 as a digital signal.

As part of an example signal-transmitting operation, the mixer 258 accepts an analog signal at BBF or IF directly or indirectly from the DAC 260. The mixer 258 upconverts the analog signal to a higher frequency, such as to an RF frequency, to produce an RF signal using a signal generated by the PLL 232 to have a target synthesized frequency. The mixer 258 provides the RF or other upconverted signal to the filter 256. The filter 256 filters the RF signal and provides a filtered signal to the power amplifier 254. Thus, after the filtering by the filter 256, the power amplifier 254 amplifies the filtered signal and provides an amplified signal to the signal propagation path 222 for signal conditioning. The RF front-end 128 can use, for instance, the duplexer circuit arrangement 130-1 of the signal propagation path 222 to provide a filtered signal to the antenna 122 for emanation as a wireless signal 220. Thus, the duplexer circuit arrangement 130-1 can duplex transmit signals and receive signals.

Example implementations of a duplexer circuit arrangement 130, as described herein, may be employed at any one or more of the example duplexer circuit arrangements 130-1 or 130-2 in the RF front-end 128 or the transceiver 126 or at other duplexing components of an electronic device 102 (not shown in FIG. 2-1). The circuitry 200-1, however, depicts just some examples for a transceiver 126 and/or an RF front-end 128. In some cases, the various components that are illustrated in the drawings using separate schematic blocks or circuit elements may be manufactured or packaged in different discrete manners. For example, one physical module may include components of the RF front-end 128 and some components of the transceiver 126, and another physical module may combine the communication processor 124 with the remaining components of the transceiver 126. Further, in some cases, the antenna 122 may be co-packaged with at least some components of the RF front-end 128 or the transceiver 126.

In alternative implementations, one or more components may be physically or logically “shifted” to a different part of the wireless interface device 120 as compared to the illustrated circuitry 200-1 and/or may be incorporated into a different module. For example, a low-noise amplifier 204 or a power amplifier 254 may alternatively or additionally be deployed in the RF front-end 128. Examples of this alternative are described next with reference to FIG. 2-2.

FIG. 2-2 is a schematic diagram 200-2 illustrating an example RF front-end 128 that can include one or more duplexer circuit arrangements coupled between at least one antenna 122 and one or more amplifiers, such as at least one low-noise amplifier (LNA) or at least one power amplifier (PA). As illustrated, the RF front-end 128 is coupled to the antenna 122 via an antenna feed line 266. Between the RF front-end 128 and the antenna 122, the antenna feed line 266 may include one or more components, such as a diplexer 264. Alternatively, the antenna feed line 266 may include a duplexing component (e.g., a duplexer circuit arrangement 130) outside of the RF front-end 128, such as in some implementations where transmit (Tx) and receive (Rx) operations share the antenna 122. The RF front-end 128 can include one or more power amplifiers and one or more low-noise amplifiers. For the illustrated example, the RF front-end 128 includes at least a power amplifier 254, a first low-noise amplifier 204-1, and a second low-noise amplifier 204-2.

The RF front-end 128 can also include multiple switches, such as a first switch 262-1, a second switch 262-2, and a third switch 262-3. The first switch 262-1 is coupled along a transmit path of a signal propagation path 222 (of FIG. 2-1) of the RF front-end 128, and the second switch 262-2 is coupled along a receive path of another signal propagation path 222. The third switch 262-3 is coupled along the transmit path and the receive path of a joint or shared signal propagation path 222 in the illustrated example. Multiple transmit or receive signal propagation paths may be established at the same time or at different times using the switches.

In example implementations, the RF front-end 128 can further include at least one duplexer circuit arrangement 130. Although not shown, one or more other duplexer circuit arrangements, duplexers, filters, and so forth may be coupled between the switches or elsewhere in the RF front-end 128. The illustrated duplexer circuit arrangement 130 can be used as part of a transmit path between the power amplifier 254 and the antenna 122, with the transmit path including the antenna feed line 266. The duplexer circuit arrangement 130 can also be used as part of a receive path between the antenna 122 and a low-noise amplifier 204, such as the first low-noise amplifier 204-1 or the second low-noise amplifier 204-2. In addition to providing duplex functionality, the duplexer circuit arrangement 130 can filter a transmit signal that is output by the power amplifier 254 and can filter a receive signal before the receive signal is input to the first or second low-noise amplifier 204-1 or 204-2.

By way of example, the first port 132-1 of the duplexer circuit arrangement 130 is coupled to the power amplifier 254 of a transmit chain (not explicitly indicated in FIG. 2-2) via the first switch 262-1. Also, the second port 132-2 of the duplexer circuit arrangement 130 is coupled to the low-noise amplifier 204-2 of a receive chain (not explicitly indicated in FIG. 2-2) via the second switch 262-2. The switches or the duplexer circuit arrangement 130 can alternatively be considered part of the transmit chain or the receive chain, including part of each chain. Further, the third port 132-3 of the duplexer circuit arrangement 130 is coupled to the antenna 122 via the third switch 262-3. The respective ports of a duplexer circuit arrangement 130 can, however, be coupled to different components or in alternative manners.

By way of example only, the second switch 262-2 is shown in a state in which the duplexer circuit arrangement 130 is coupled to an input of the second low-noise amplifier 204-2. The first switch 262-1 is shown in a state in which the duplexer circuit arrangement 130 is coupled to an output of the power amplifier 254. The duplexer circuit arrangement, switches, amplifiers, signal propagation paths (and other non-illustrated components) can, however, be realized or operationally configured in different manners. The transmit and receive paths can be established using one or more of the first, second, or third switches 262-1, 262-2, or 262-3. A controller (not shown), which may be part of the communication processor 124 (of FIGS. 1 and 2-1), can position or set the states of these switches based on a transmit versus receive mode, a frequency being used for transmission or reception, the feasibility of duplexed communications, and so forth. Although certain components are depicted in FIG. 2-2 in certain arrangements and described above in a particular manner, an RF front-end 128 can include different components, more or fewer components, different couplings or arrangements of the components, and so forth.

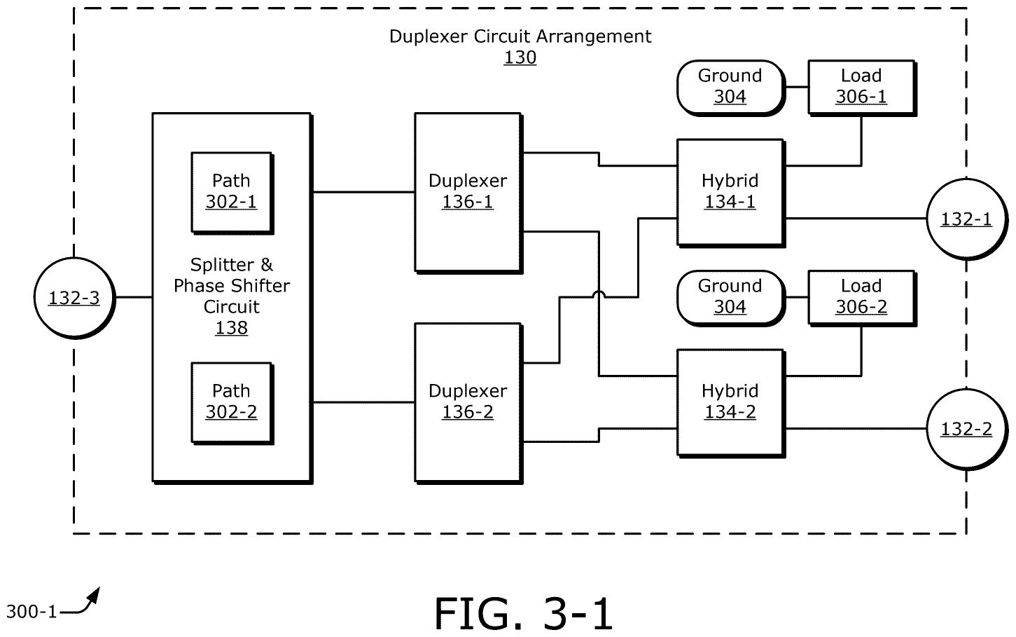

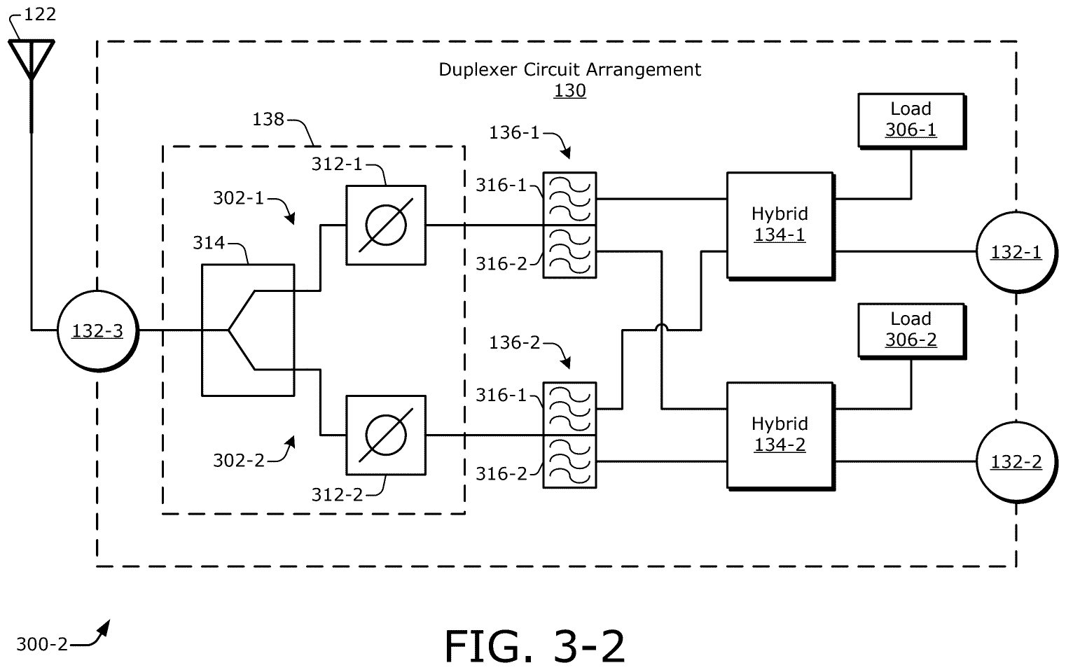

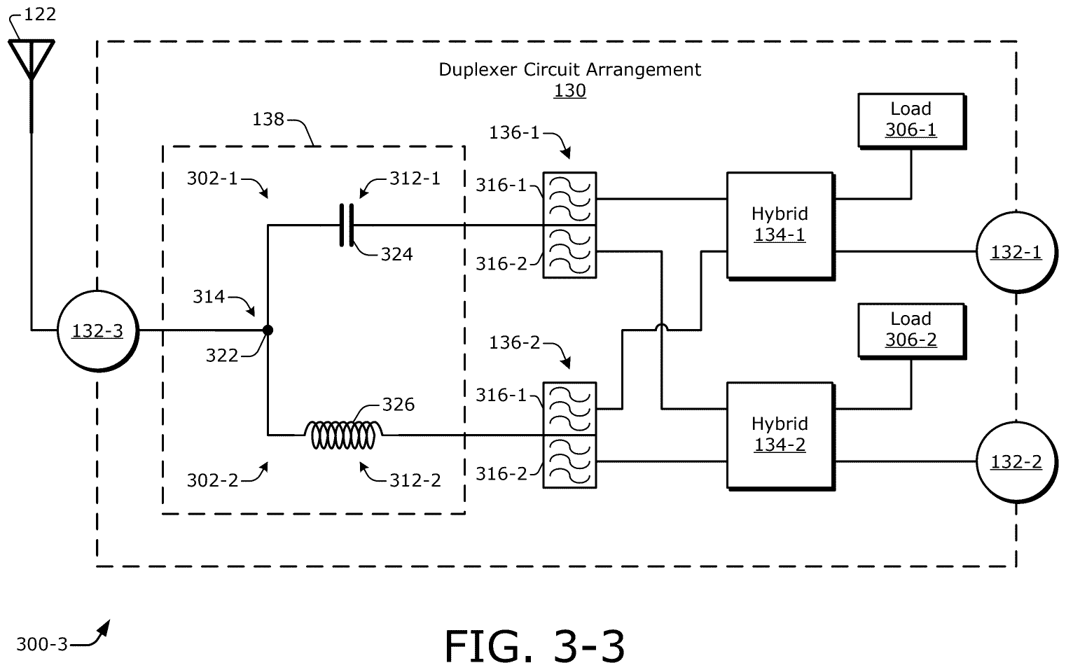

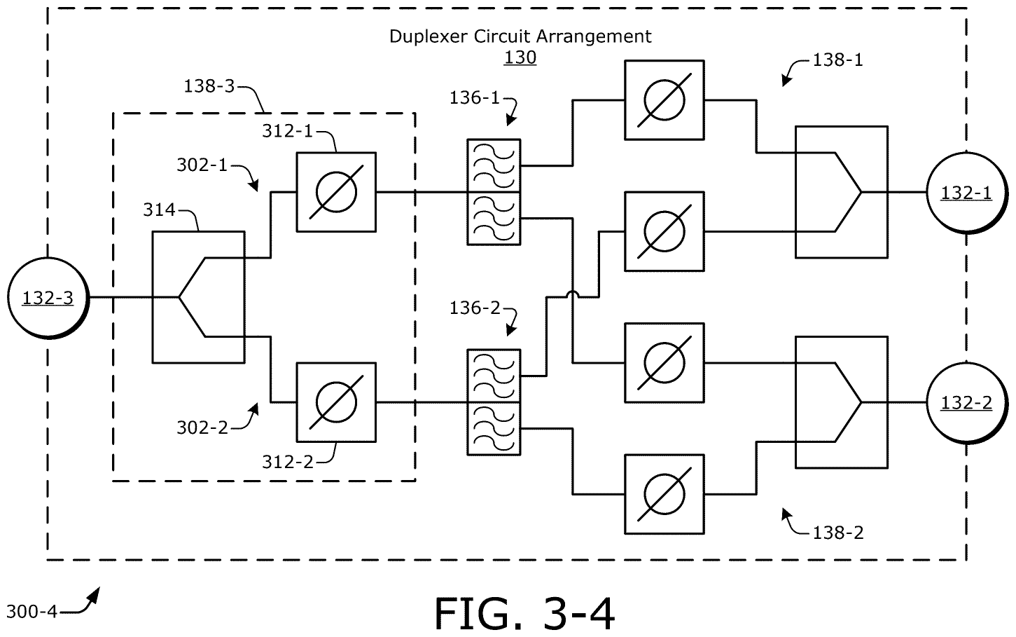

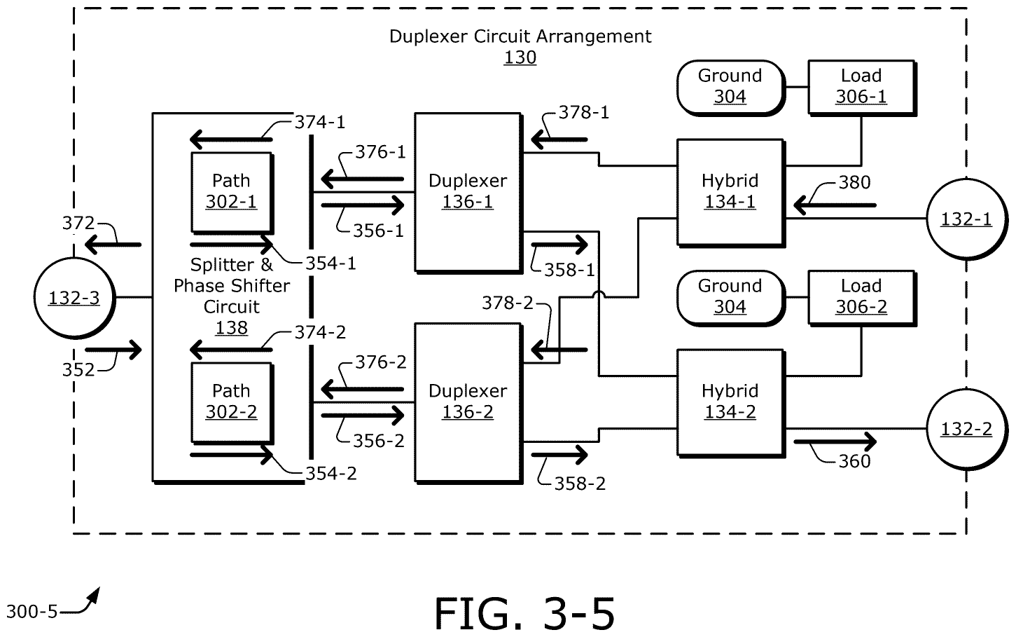

FIGS. 3-1 to 3-5 illustrate example approaches to implementing a smaller or simpler duplexer circuit arrangement 130 using at least one splitter and phase shifter circuit 138. With reference to FIG. 3-1, at 300-1 generally, the example duplexer circuit arrangement 130 includes at least one port 132, at least one hybrid 134, at least one duplexer 136, and at least one load 306. Each hybrid 134 can be implemented, for example, as a hybrid coupler, such as a quadrature hybrid coupler, which is also referred to as a ninety-degree (90°) hybrid coupler. A hybrid 134 can be realized as a multi-port circuit device, such as a three-port or four-port device. In example operations, an input signal at an input port can be split approximately equally between two output ports. With a quadrature hybrid coupler, the phase difference between the two output signals is approximately 90 degrees relative to each other. If a hybrid coupler includes a fourth port, a reflected signal component that arises from the two outputs (e.g., due to impedance mismatch) can be absorbed in a load connected to the fourth port.

As illustrated, the duplexer circuit arrangement 130 includes three ports 132-1, 132-2, and 132-3; two hybrids 134-1 and 134-2; two duplexers 136-1 and 136-2; one splitter and phase shifter circuit 138; and two loads 306-1 and 306-2. A duplexer circuit arrangement 130 can, however, include more or fewer of any such components or other components. The splitter and phase shifter circuit 138 includes at least one path 302. Although the quantity of paths may be different, the illustrated splitter and phase shifter circuit 138 includes two paths 302-1 and 302-2.

In example implementations, the various components are coupled between two or more of the first port 132-1, the second port 132-2, or the third port 132-3. The first hybrid 134-1 is coupled between the first port 132-1 and the first duplexer 136-1 and between the first port 132-1 and the second duplexer 136-2. The second hybrid 134-2 is coupled between the second port 132-2 and the second duplexer 136-2 and between the second port 132-2 and the first duplexer 136-1. The splitter and phase shifter circuit 138 is coupled between the third port 132-3 and the first and second duplexers 136-1 and 136-2. The first load 306-1 is coupled between the first hybrid 134-1 and a ground 304, and the second load 306-2 is coupled between the second hybrid 134-2 and the ground 304. For clarity, the ground 304 (e.g., a ground node or a ground plane) is omitted from some of the other figures.

In some cases, the splitter and phase shifter circuit 138 includes the first path 302-1 and the second path 302-2. In example operation, the splitter and phase shifter circuit 138 is configured to shift a relative phase between a first signal propagating on the first path 302-1 and a second signal propagating on the second path 302-2. The relative phase shift can be approximately ninety degrees, but need not be exactly 0° and 90°, as is described below. The relative phase shift can be formed using one phase shifter, two phase shifters, or more. For a 90° phase shift, for instance, one phase shifter can shift one propagating signal by the “full” 90°. Alternatively, two phase shifters can each shift a portion of the “full” 90°. For instance, one phase shifter may produce a 60° phase shift, and another phase shifter may produce a 30° phase shift. For superior symmetry, however, each phase shifter can shift the phase of a respective propagating signal by 45°.

With reference also to FIGS. 2-1 and 2-2, for an example RF environment, the first port 132-1 is configured to be coupled to an output of a power amplifier 254. The second port 132-2 is configured to be coupled to an input of a low-noise amplifier 204, such as the second low-noise amplifier 204-2. The third port 132-3 is configured to be coupled to an antenna 122. When the duplexer circuit arrangement 130 is connected to other portions of a wireless interface device 120 (e.g., as part of an electronic device 102), these ports 132-1 to 132-3 of the duplexer circuit arrangement 130 may be coupled to the indicated interfaces. Further, there may be one or more other components coupled between any of these ports and the indicated component input, component output, or antenna terminal. Generally, the port being most susceptible to changes in the load-impedance is the antenna port. The loads at the power-amplifier-hybrid and the low-noise-amplifier-hybrid can be used to consume the reflected power caused by a mismatched antenna. In contrast, because the low-noise amplifier and the power amplifier can be well-matched, the load at an antenna-hybrid becomes less helpful. This enables the antenna-hybrid to be replaced by a simpler structure, such as one that provides a relative 90-degree phase-shift between the transmit and receive paths without having a load.

With reference to FIG. 3-2, at 300-2 generally, the splitter and phase shifter circuit 138 can include at least one signal phase shifter 312 and at least one signal splitter 314. Although one signal splitter 314 and two signal phase shifters 312-1 and 312-2 are explicitly depicted, a splitter and phase shifter circuit 138 may have an alternative quantity of either component or other components. In the illustrated example, the splitter and phase shifter circuit 138 includes the signal splitter 314 coupled to the third port 132-3. The splitter and phase shifter circuit 138 also includes a first path 302-1 coupled between the signal splitter 314 and the first duplexer 136-1 and a second path 302-2 coupled between the signal splitter 314 and the second duplexer 136-2. At least one signal phase shifter 312 is coupled along at least one of the first path 302-1 or the second path 302-2. However, none or multiple signal phase shifters may be coupled along the same path.

In some implementations, the at least one signal phase shifter 312 includes a first signal phase shifter 312-1 and a second signal phase shifter 312-2. The first path 302-1 includes the first signal phase shifter 312-1, and the second path 302-2 includes the second signal phase shifter 312-2. In example operations, the first signal phase shifter 312-1 and the second signal phase shifter 312-2 can shift a relative phase between a first signal propagating on the first path 302-1 and a second signal propagating on the second path 302-2 by approximately ninety degrees (90°). In some cases, the two signal phase shifters are architected to combine to be as close as possible to 90°, with a given technology and cost envelope. For example, approximately ninety degrees may include, in addition to being exactly 90°, 89.5°, 88°, or even 85°.

As depicted in FIG. 3-2, each duplexer 136 can include one or more filters, such as two filters. As explicitly indicated for the first duplexer 136-1, each duplexer 136 can include a first filter 316-1 and a second filter 316-2. Each filter 316 may be formed from or include at least one acoustic filter, at least one inductor, at least one capacitor, some combination thereof, and so forth. Each filter 316 may comprise a tunable component, at least during the design stage of development or the manufacturing phase of production. Each filter 316 may be designed to suppress or pass particular frequencies to support a duplexing operation. For instance, the first filter 316-1 may target transmission frequencies in a passband, and the second filter 316-2 may target reception frequencies in a passband.

In example implementations, the first duplexer 136-1 is substantially similar to the second duplexer 136-2. In some cases, the first filter 316-1 of the first duplexer 136-1 can be at least substantially similar to the first filter 316-1 of the second duplexer 136-2, and the second filter 316-2 of the first duplexer 136-1 can be at least substantially similar to the second filter 316-2 of the second duplexer 136-2. Each respective filter 316 of each duplexer 136 can be architected to be the same as the corresponding respective filter 316 of the other duplexer 136. Thus, each respective filter 316 can be identical to its corresponding filter 316 in a different duplexer 136 within the manufacturing tolerances of a particular technology and given economically customary expenditures.

By way of example only, the first duplexer 136-1 can be configured to target at least one given frequency range, and the second duplexer 136-2 can also be configured to target the at least one given frequency range. A targeted frequency range may be implemented on a per-filter basis. From a structural (e.g., dimensional) or materials perspective, to be substantially similar, the physical characteristics of the second duplexer 136-2 can be within ten percent (10%), five percent (5%), or one percent (1%) of (or identical to) the physical characteristics of the first duplexer 136-1.

With reference to FIG. 3-3, at 300-3 generally, the splitter and phase shifter circuit 138 can include the signal splitter 314, the first signal phase shifter 312-1, and the second signal phase shifter 312-2. In example implementations, the signal splitter 314 includes at least one node 322. Additionally, the first phase shifter 312-1 includes at least one capacitor 324, and the second phase shifter 312-2 includes at least one inductor 326. In some cases, the at least one inductor 326 is impedance-matched to the antenna 122 that is coupled to the third port 132-3. Similarly, the at least one capacitor 324 is impedance-matched to the antenna 122 that is coupled to the third port 132-3.

Although one capacitor 324 and one inductor 326 are explicitly depicted, each branch may have more than one such component. Further, at the cost of some simplicity, each branch may have a combination of inductors and capacitors. By including one or more inductors (but not a capacitor) in one branch and one or more capacitors (but not an inductor) in the other branch, however, a simpler circuit is maintained that can shift propagating signals by 45° in each branch, for a total of a 90° relative phase difference.

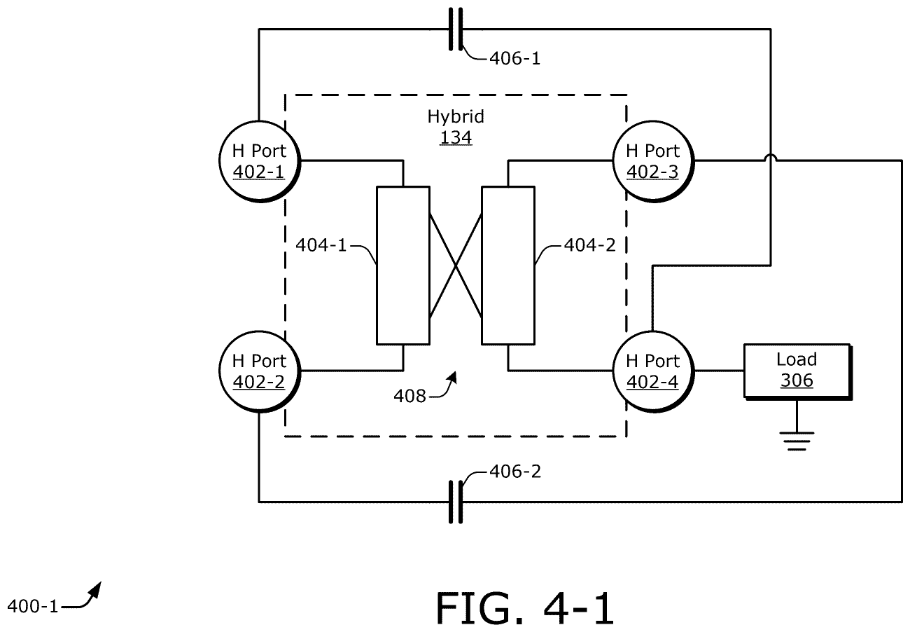

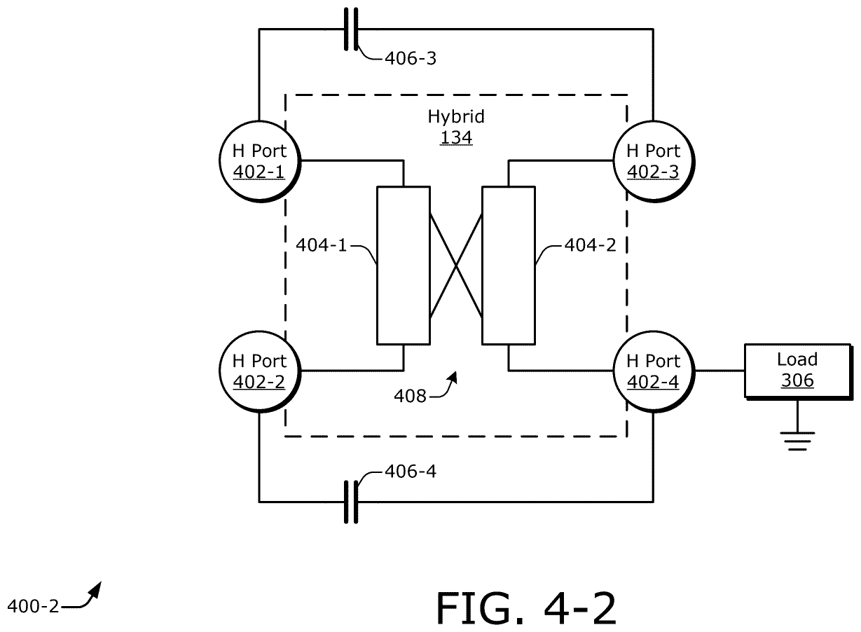

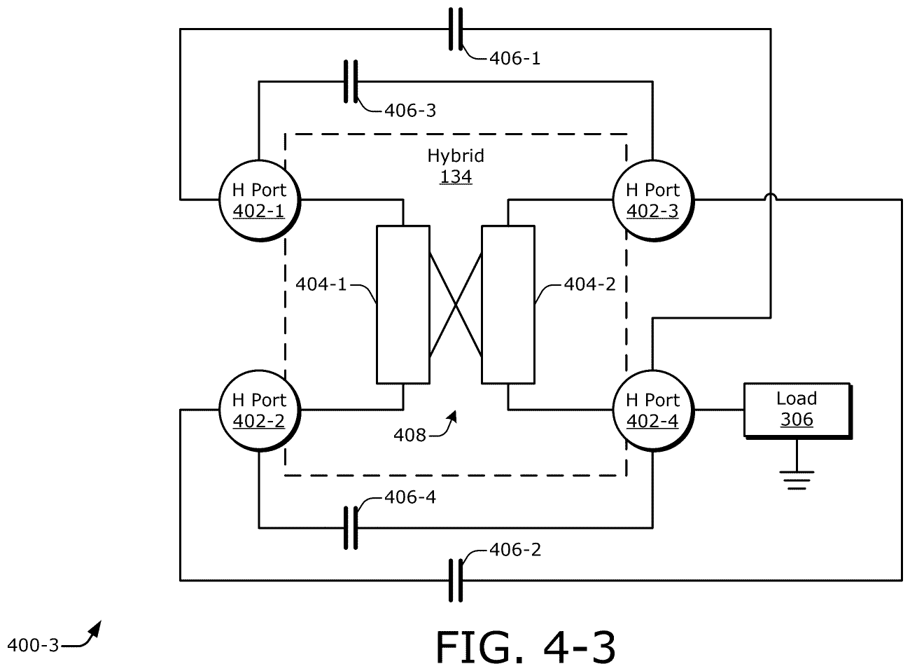

With reference to FIG. 3-4, at 300-4 generally, the example duplexer circuit arrangement 130 can include multiple instances of a splitter and phase shifter circuit 138. As illustrated, the duplexer circuit arrangement 130 includes three splitter and phase shifter circuits 138-1, 138-2, and 138-3. Each splitter and phase shifter circuit 138 can include, for instance, one signal splitter 314 and two signal phase shifters 312-1 and 312-2. A first splitter and phase shifter circuit 138-1 is coupled between the first port 132-1 and the first and second duplexers 136-1 and 136-2. A second splitter and phase shifter circuit 138-2 is coupled between the second port 132-2 and the first and second duplexers 136-1 and 136-2. A third splitter and phase shifter circuit 138-3 is coupled between the third port 132-3 and the first and second duplexers 136-1 and 136-2.

Thus, compared to FIGS. 3-1 to 3-3, in FIG. 3-4 the first and second hybrids 134-1 and 134-2 are “replaced” with the first and second splitter and phase shifter circuits 138-1 and 138-2. However, one or the other hybrid 134 (but not necessarily both) may be replaced with a splitter and phase shifter circuit 138. Further, the third splitter and phase shifter circuit 138-3 may be implemented with a hybrid 134. Generally, any combination of one or more hybrids or one or more splitter and phase shifter circuits may be employed in a duplexer circuit arrangement 130 between the duplexers and ports.

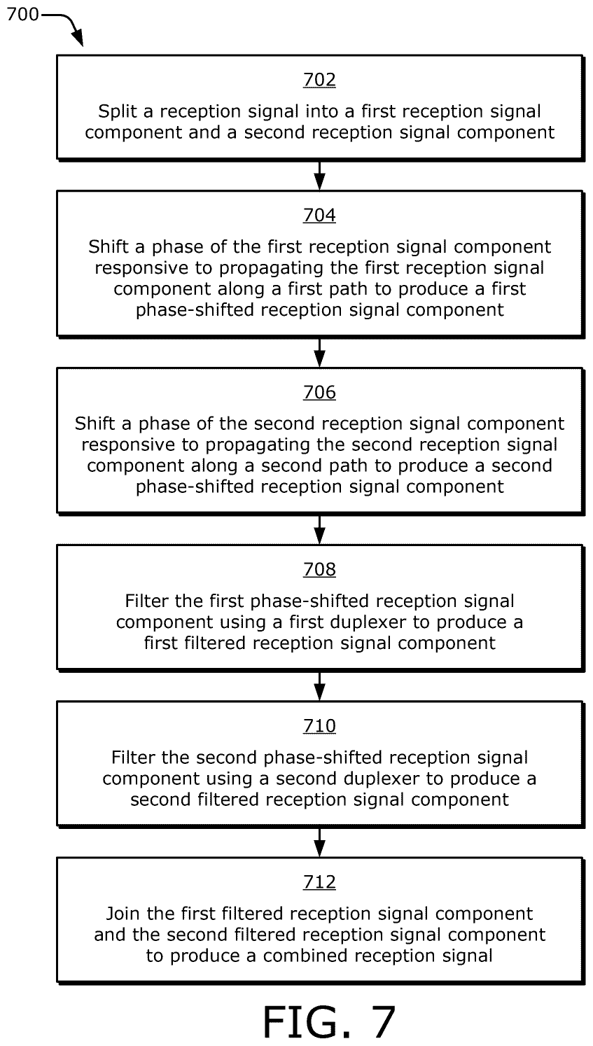

With reference to FIG. 3-5, at 300-5 generally, multiple example signals that can propagate through a duplexer circuit arrangement 130 are depicted. For an example reception operation, these signals can include a reception signal 352, a first reception signal component 354-1, a second reception signal component 354-2, a first phase-shifted reception signal component 356-1, and a second phase-shifted reception signal component 356-2. The relative phase difference between the first phase-shifted reception signal component 356-1 and the second phase-shifted reception signal component 356-2 may be, for instance, 90°. Reception operation signals can also include a first filtered reception signal component 358-1, a second filtered reception signal component 358-2, and a combined reception signal 360. The second hybrid 134-2 can substantially “remove” the phase difference responsive to the signal joining that produces the combined reception signal 360. An example signal reception operation that relates to these signals is described below with reference to FIG. 7.

For a transmission operation, these signals can include a transmission signal 380, a first transmission signal component 378-1, a second transmission signal component 378-2, a first filtered transmission signal component 376-1, and a second filtered transmission signal component 376-2. The first hybrid 134-1 can create a relative phase difference (e.g., of) 90° responsive to producing the first transmission signal component 378-1 and the second transmission signal component 378-2 by separating the transmission signal 380 into two components. Accordingly, the first filtered transmission signal component 376-1 and the second filtered transmission signal component 376-2 maintain this relative phase difference. Transmission operation signals can also include a first phase-shifted transmission signal component 374-1, a second phase-shifted transmission signal component 374-2, and a combined transmission signal 372. The splitter and phase shifter circuit 138 can substantially “remove” the relative phase difference between the first phase-shifted transmission signal component 374-1 and the second phase-shifted transmission signal component 374-2 as part of a phase-shifting and signal combining operation. An example signal transmission operation that relates to these signals is described below with regard to the reception operation illustrated by FIG. 7.

FIGS. 4-1 to 4-3 illustrate example approaches to reducing the size of a hybrid 134, such as one that is part of duplexer circuit arrangement. With reference to FIG. 4-1, at 400-1 generally, the hybrid 134 can include multiple hybrid ports, such as four hybrid ports 402-1, 402-2, 402-3, and 402-4. A hybrid 134 can be constructed in different manners. In example implementations, the hybrid 134 can be formed using one or more transmission lines, such as two lines 404-1 and 404-2. A coupled-line structure 408, which includes two lines that are electromagnetically coupled together, can have different geometries for the lines.

Generally, reducing a length or a width of a line 404 can produce a smaller hybrid 134, which results in a smaller and less expensive duplexer circuit arrangement. A coupled-line structure 408 with a load provides good matching and a 90° phase difference, even if the lines 404-1 and 404-2 are short. The length of each line 404 mainly impacts the power split between branches of the hybrid 134.

When the lines 404-1 and 404-2 are shorter, a larger portion of the signal travels from the first hybrid port 402-1 to the second hybrid port 402-2. Although a capacitor can be coupled between the first and third hybrid ports 402-1 and 402-3 to increase the coupling between these two ports, such a capacitor placement can appreciably degrade the matching. Instead, a second capacitor 406-2 can be coupled between the second hybrid port 402-2 and the third hybrid port 402-3 to increase the balancing of the power split between the two branches.

This second capacitor 406-2, however, can degrade the phase difference. To compensate for this potential phase difference degradation, a first capacitor 406-1 can be coupled between the first hybrid port 402-1 and the fourth hybrid port 402-4. Here, the load 306 is coupled to the fourth hybrid port 402-4. By including the first and second capacitors 406-1 and 406-2 as depicted at 400-1, the length of the lines 404-1 and 404-2 of the hybrid 134 can be reduced. In one instance, similar performance was achieved after shortening the lengths of the lines 404-1 and 404-2 by 30% with the “addition” of the first and second capacitors 406-1 and 406-2 as depicted at 400-1.

With reference to FIG. 4-2, at 400-2 generally, the width of the lines 404-1 and 404-2 can also or alternatively be reduced. To reduce the line widths without unduly decreasing performance, two capacitors can be coupled to the hybrid 134 in different manners as compared to the couplings of FIG. 4-1. In example implementations, a first capacitor 406-3 can be coupled between the first hybrid port 402-1 and the third hybrid port 402-3. Additionally, a second capacitor 406-4 can be coupled between the second hybrid port 402-2 and the fourth hybrid port 402-4. The load 306 is coupled to the fourth hybrid port 402-4 in this example. Although employing these two capacitors can enable the lines 404-1 and 404-2 to be widened while substantially maintaining the matching and phase-difference performances, such capacitances can lead to the circuit becoming more narrowband.

With reference to FIG. 4-3, at 400-3 generally, the two capacitors depicted in FIG. 4-1 and the two capacitors depicted in FIG. 4-2 can be employed together with one hybrid 134. With the inclusion of four capacitors, instead of two, the numeric-related naming of the capacitors is adjusted for the description of FIG. 4-3. In example implementations, four capacitors are coupled to the hybrid 134: a first capacitor 406-1, a second capacitor 406-2, a third capacitor 406-3, and a fourth capacitor 406-4. The hybrid 134 includes a first hybrid port 402-1, a second hybrid port 402-2, a third hybrid port 402-3, and a fourth hybrid port 402-4. With reference also to, e.g., FIG. 3-1, the first hybrid port 402-1 is coupled to a first duplexer 136-1, and the second hybrid port 402-2 is coupled to a second duplexer 136-2. The third hybrid port 402-3 is coupled to a port 132 of a duplexer circuit arrangement 130, such as a first port 132-1 or a second port 132-2. The fourth hybrid port 402-4 is coupled to a load 306 as shown.

The first capacitor 406-1 is coupled between the first hybrid port 402-1 and the fourth hybrid port 402-4. The second capacitor 406-2 is coupled between the second hybrid port 402-2 and the third hybrid port 402-3. The third capacitor 406-3 is coupled between the first hybrid port 402-1 and the third hybrid port 402-3. The fourth capacitor 406-4 is coupled between the second hybrid port 402-2 and the fourth hybrid port 402-4.

FIGS. 5-1 and 5-2 illustrate example approaches to increasing isolation with a duplexer circuit arrangement using at least one hybrid 134. In these example implementations, isolation is increased by tuning the length or width (including the length and the width in some cases) of the bindings of the hybrid 134. With a duplexer circuit arrangement 130, in order to cancel the transmit and receive signals appropriately, the phase difference between two branches of the hybrid 134 is made to be approximately 90°. For example, the phases of first and second signal components can be separate from each other by 90°, 89°, 88°, or even 87°. However, the absolute phase of each branch can vary. Accordingly, the length or width of the lines of the coupled line structure 408 can be tuned to increase isolation even if the absolute phases of the signal components of the branches deviate from 0° and 90°.

For example, consider that a hybrid 134 is configured to couple a signal with regard to a first signal component and a second signal component. The signal has a phase, the first signal component has a first phase, and the second signal component has a second phase. Based on adjusting the length or width of the bindings, the first phase and the second phase can each be substantially different from the phase. To be substantially different, the first phase and the second phase can each vary from the phase by at least thirty degrees (30°), at least twenty degrees (20°), at least ten degrees (10°), or even at least five degrees (5°). Examples for the first and second phases include 17 and −73 degrees and 8 and −82 degrees, each pair of which represents a separation of approximately 90 degrees. Generally, the phase deviation from 0° and 90° is greater than what might occur due to manufacturing defects or production variations.

To maintain performance of the duplexer circuit arrangement 130, each other hybrid 134 that is part of the duplexer circuit arrangement 130 can operate with the approximately same relative phase differences. This creates a global phase offset for the duplexer circuit arrangement 130. This global phase offset may be established using, for instance, bindings with similar lengths and widths in each of multiple hybrids. For example, a first phase of a first signal component and a second phase of a second signal component of a second hybrid can each be substantially different from the phase of a signal of the second hybrid by an amount that is at least approximately equivalent to how much the first phase of the first signal component and the second phase of the second signal component of the first hybrid are each substantially different from the phase of the signal of the first hybrid. In this context, approximately equivalent can be, in addition to being exactly equivalent, within one degree (1°), two degrees (2°), or even three degrees (3°) of each other.

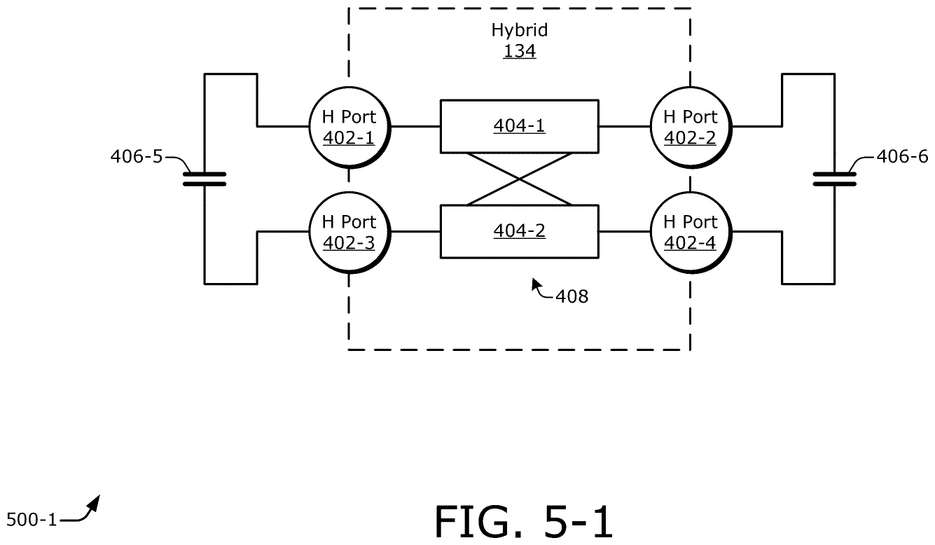

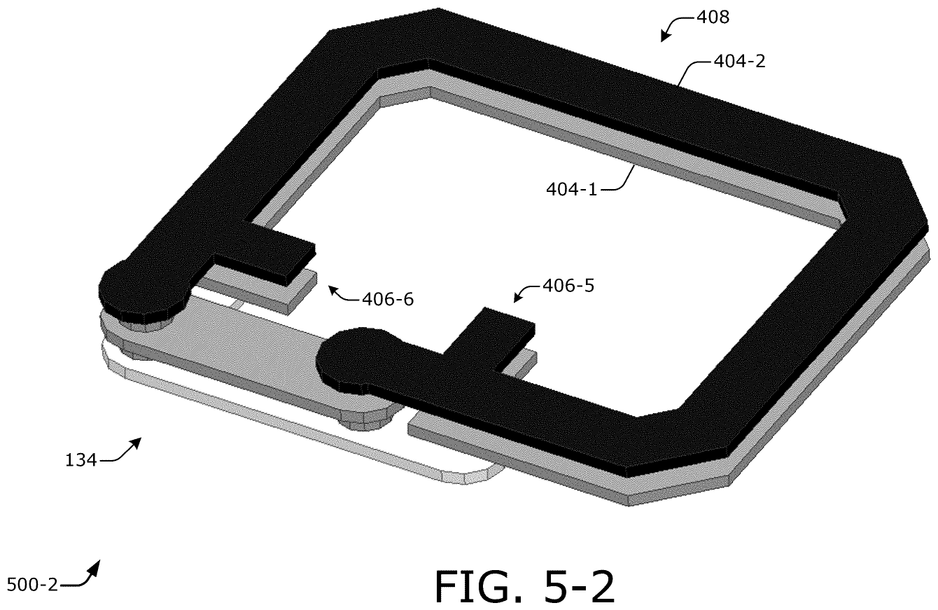

In one instance tuning the length and width of the binding of a hybrid increased isolation by 15 decibels (15 dB). The isolation can be increased still further by “adding” capacitors between pairs of terminals, as is shown in FIG. 5-1. In example implementations, with reference to 500-1 generally, a duplexer circuit arrangement 130 (e.g., of any of FIGS. 1 to 3-3) includes a hybrid 134, a first capacitor 406-5, and a second capacitor 406-6. The hybrid 134 includes a first hybrid port 402-1, a second hybrid port 402-2, a third hybrid port 402-3, and a fourth hybrid port 402-4. The first hybrid port 402-1 is coupled to a first duplexer 136-1 (e.g., of FIG. 3-1), and the second hybrid port 402-2 is coupled to a second duplexer 136-2. The third hybrid port 402-3 is coupled to a port 132 of the duplexer circuit arrangement 130, such as a first port 132-1 or a second port 132-2. The first capacitor 406-5 is coupled between the first hybrid port 402-1 and the third hybrid port 402-3. The second capacitor 406-6 is coupled between the second hybrid port 402-2 and the fourth hybrid port 402-4.

With reference to FIGS. 5-2, and 500-2 generally, a respective capacitor 406 is included between the terminals of a hybrid 134. Thus, in some cases, capacitance can be added by incorporating first and second capacitors 406-5 and 406-6 “directly” at the hybrid ports (e.g., terminals) of the hybrid 134 as shown. Capacitance can be subtracted by reducing a width of a least one line 404 or offsetting the two lines. The first capacitor 406-5 or the second capacitor 406-6 can, however, be fabricated in a different manner or at a different location.

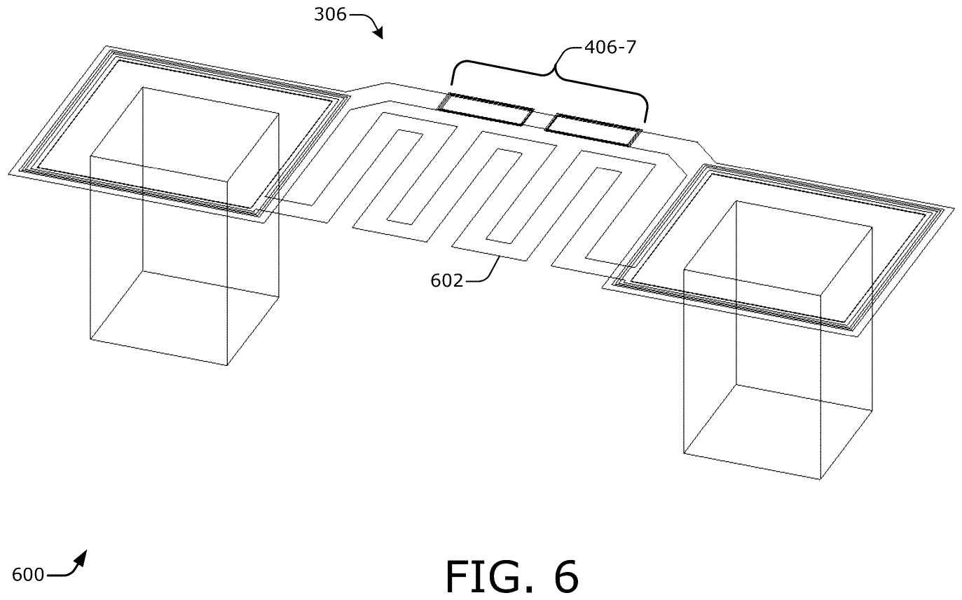

FIG. 6 illustrates, at 600 generally, example approaches to increasing isolation with a duplexer circuit arrangement 130 using at least one load 306. With reference also to, e.g., FIG. 3-1, a load 306 (e.g., at fifty Ohms) can be implemented using a surface-mount device (SMD) resistor in terms of achieving a targeted resistance and production tolerances. The inductive interconnects, however, would appreciably degrade the isolation (e.g., by about 20 dB in some instances). Thus, in accordance with example implementations, the load 306 is instead realized in an acoustic chip for a duplexer circuit arrangement 130 that employs one or more acoustic filters in a duplexer 136. Although the inductive parasitics for this resistor integration might also be initially problematic, a capacitor can be integrated in parallel with the load to compensate for the inductive parasitics. Further, this capacitor can also compensate for other routings on the laminate.

With continuing reference to FIG. 6 (and, e.g., FIG. 3-1), an example load 306, which is coupled to a hybrid 134, is realized as at least one resistor 602. To save space, the resistor 602 can be implemented using a meandered line as shown. To counteract inductive parasitics, a capacitor 406-7 can be incorporated as part of the load 306. The capacitor 406-7 can be coupled to, and in parallel with, the resistor 602. The meandered line can be disposed in or on a laminate of an acoustic filter die. The acoustic filter die may include at least one acoustic filter for at least one duplexer 136 of a duplexer circuit arrangement 130.

FIG. 7 is a flow diagram illustrating an example process 700 for operating at least one duplexer circuit arrangement. The process 700 includes six blocks 702-712 that specify operations that can be performed for a method. However, operations are not necessarily limited to the order shown in the figures or described herein, for the operations may be implemented in alternative orders or in fully or partially overlapping manners. Also, more, fewer, and/or different operations may be implemented to perform a respective process or an alternative process.

In example implementations, operations represented by the illustrated blocks of each process may be performed by an electronic device, such as the electronic device 102 of FIG. 1 or the wireless interface device 120 thereof. More specifically, the operations of the respective processes may be performed by a duplexer circuit arrangement 130 of a transceiver 126 or an RF front-end 128. Although some of the description herein focusses on a duplexer circuit arrangement 130 that operates on RF signals, the described principles (e.g., corresponding to devices, circuitry, techniques, and processes) are not so limited. These principles are also applicable to signals at other frequencies.

At block 702, a reception signal is split into a first reception signal component and a second reception signal component. For example, a splitter and phase shifter circuit 138 can split a reception signal 352 into a first reception signal component 354-1 and a second reception signal component 354-2. For instance, a signal splitter 314 may split an incoming received signal into two components having a same phase and route the two components along two different paths as shown in, e.g., FIG. 3-5.

At block 704, a phase of the first reception signal component is shifted responsive to propagating the first reception signal component along a first path to produce a first phase-shifted reception signal component. For example, a first signal phase shifter 312-1 can shift a phase of the first reception signal component 354-1 responsive to propagating the first reception signal component 354-1 along a first path 302-1 to produce a first phase-shifted reception signal component 356-1. In some cases, the first signal phase shifter 312-1 can be realized with a transmission line.

At block 706, a phase of the second reception signal component is shifted responsive to propagating the second reception signal component along a second path to produce a second phase-shifted reception signal component. For example, a second signal phase shifter 312-2 can shift a phase of the second reception signal component 354-2 responsive to propagating the second reception signal component 354-2 along a second path 302-2 to produce a second phase-shifted reception signal component 356-2. To do so, first and second signal phase shifters 312-1 and 312-2 can respectively include a capacitor and an inductor as shown in, e.g., FIG. 3-3.

At block 708, the first phase-shifted reception signal component is filtered using a first duplexer to produce a first filtered reception signal component. For example, a first duplexer 136-1 can filter the first phase-shifted reception signal component 356-1 to produce a first filtered reception signal component 358-1. Here, a filter 316 of the first duplexer 136-1 may bandpass filter the first phase-shifted reception signal component 356-1 based on a targeted receiving frequency range as shown in, e.g., FIG. 3-2.

At block 710, the second phase-shifted reception signal component is filtered using a second duplexer to produce a second filtered reception signal component. For example, a second duplexer 136-2 can filter the second phase-shifted reception signal component 356-2 to produce a second filtered reception signal component 358-2. Thus, the first and second filtered reception signal components 358-1 and 358-2 continue to have a phase difference (e.g., approximately 90°) that is created by the splitter and phase shifter circuit 138.

At block 712, the first filtered reception signal component and the second filtered reception signal component are joined to produce a combined reception signal. For example, a second hybrid 134-2 can join the first filtered reception signal component 358-1 and the second filtered reception signal component 358-2 to produce a combined reception signal 360. This may be performed by, for instance, a hybrid having a coupled line structure 408 in conjunction with one or more of the alternative implementations described herein. These include adjusting a length or width of the coupled lines of the hybrid to reduce a size of the hybrid, changing the bindings of the coupled lines of the hybrid to create a global phase offset, connecting one or more capacitors to the hybrid ports of the hybrid, integrating a load for the hybrid into an acoustic filter chip, and so forth. The second hybrid 134-2 can forward the combined reception signal 360 to a second port 132-2. The operation(s) of block 712 can alternatively be performed by another splitter and phase shifter circuit.

The process 700 of FIG. 7 is directed to processing a receive signal arriving from an antenna. A duplexer circuit arrangement 130, however, can also be used to process a transmit signal propagating towards the antenna. To do so, in accordance with example implementations, a first hybrid 134-1 can accept a transmission signal 380 from a first port 132-1 and separate the transmission signal 380 into a first transmission signal component 378-1 and a second transmission signal component 378-2. Here, the first transmission signal component 378-1 and the second transmission signal component 378-2 have different phases (e.g., that are separated by 90°) based on the operation of the first hybrid 134-1.

A first duplexer 136-1 can filter the first transmission signal component 378-1 to produce a first filtered transmission signal component 376-1. A second duplexer 136-2 can filter the second transmission signal component 378-2 to produce a second filtered transmission signal component 376-2.

A splitter and phase shifter circuit 138 can shift a phase of the first filtered transmission signal component 376-1 responsive to propagating the first filtered transmission signal component along a first path 302-1 to produce a first phase-shifted transmission signal component 374-1. The splitter and phase shifter circuit 138 can also shift a phase of the second filtered transmission signal component 376-2 responsive to propagating the second filtered transmission signal component 376-2 along the second path 302-2 to produce a second phase-shifted transmission signal component 374-2. Thus, the first phase-shifted transmission signal component 374-1 and the second phase-shifted transmission signal component 374-2 can be returned to having a same phase “after” the phases were separated by the first hybrid 134-1.

The splitter and phase shifter circuit 138 can further combine the first phase-shifted transmission signal component 374-1 and the second phase-shifted transmission signal component 374-2 to produce a combined transmission signal 372. The splitter and phase shifter circuit 138 can forward the combined transmission signal 372 to a third port 132-3 of the duplexer circuit arrangement 130 for further propagation to an antenna 122.

### IMPLEMENTATION EXAMPLES

This section describes some aspects of example implementations and/or example configurations related to the apparatuses and/or processes presented above.

Example aspect 1: An apparatus comprising:
at least one duplexer circuit arrangement comprising:
   a first port, a second port, and a third port;
   a first duplexer and a second duplexer;
   a first hybrid coupled between the first port and the first duplexer and between the first port and the second duplexer;
   a second hybrid coupled between the second port and the second duplexer and between the second port and the first duplexer; and
   a splitter and phase shifter circuit coupled between the third port and the first and second duplexers.

Example aspect 2: The apparatus of example aspect 1, wherein:
the splitter and phase shifter circuit comprises a first path and a second path; and the splitter and phase shifter circuit is configured to shift a relative phase between
a first signal propagating on the first path and a second signal propagating on the second path.

Example aspect 3: The apparatus of example aspect 1 or 2, wherein:
the first port is configured to be coupled to an output of a power amplifier;
the second port is configured to be coupled to an input of a low-noise amplifier; and
the third port is configured to be coupled to an antenna.

Example aspect 4: The apparatus of any one of the preceding example aspects, wherein the splitter and phase shifter circuit comprises:
a signal splitter coupled to the third port;
a first path coupled between the signal splitter and the first duplexer;
a second path coupled between the signal splitter and the second duplexer; and
at least one signal phase shifter coupled along at least one of the first path or the second path.

Example aspect 5: The apparatus of example aspect 4, wherein:
the at least one signal phase shifter comprises a first signal phase shifter and a second signal phase shifter;
the first path comprises the first signal phase shifter; and
the second path comprises the second signal phase shifter.

Example aspect 6: The apparatus of example aspect 5, wherein:
the first signal phase shifter and the second signal phase shifter are configured to shift a relative phase between a first signal propagating on the first path and a second signal propagating on the second path by approximately ninety degrees (90°).

Example aspect 7: The apparatus of example aspect 5 or 6, wherein:
the signal splitter comprises a node;
the first signal phase shifter comprises at least one capacitor; and the second signal phase shifter comprises at least one inductor.

Example aspect 8: The apparatus of example aspect 7, wherein at least one of:
the at least one inductor is impedance-matched to an antenna that is coupled to the third port; or
the at least one capacitor is impedance-matched to the antenna that is coupled to the third port.

Example aspect 9: The apparatus of any one of the preceding example aspects, wherein the first duplexer and the second duplexer are substantially similar.

Example aspect 10: The apparatus of any one of the preceding example aspects, wherein:
the first duplexer is configured to target at least one given frequency range; and
the second duplexer is configured to target the at least one given frequency range.

Example aspect 11: The apparatus of any one of the preceding example aspects, wherein physical characteristics of the second duplexer are within ten percent (10%) of physical characteristics of the first duplexer.

Example aspect 12: The apparatus of any one of the preceding example aspects, wherein:
the at least one duplexer circuit arrangement further comprises:
   a load;
   a first capacitor; and
   a second capacitor;
the first hybrid comprises a first hybrid port, a second hybrid port, a third hybrid
port, and a fourth hybrid port;
the first hybrid port is coupled to the first duplexer;
the second hybrid port is coupled to the second duplexer;
the third hybrid port is coupled to the first port;
the fourth hybrid port is coupled to the load;
the first capacitor is coupled between the first hybrid port and the fourth hybrid port; and
the second capacitor is coupled between the second hybrid port and the third hybrid port.

Example aspect 13: The apparatus of example aspect 12, wherein:
the at least one duplexer circuit arrangement further comprises:
   a third capacitor; and
   a fourth capacitor;
the third capacitor is coupled between the first hybrid port and the third hybrid port; and
the fourth capacitor is coupled between the second hybrid port and the fourth hybrid port.

Example aspect 14: The apparatus of any one of the preceding example aspects, wherein:
the at least one duplexer circuit arrangement further comprises:
   a load;
   a first capacitor; and
   a second capacitor;
the first hybrid comprises a first hybrid port, a second hybrid port, a third hybrid port, and a fourth hybrid port;
the first hybrid port is coupled to the first duplexer;
the second hybrid port is coupled to the second duplexer;
the third hybrid port is coupled to the first port;
the fourth hybrid port is coupled to the load;
the first capacitor is coupled between the first hybrid port and the third hybrid port; and
the second capacitor is coupled between the second hybrid port and the fourth hybrid port.

Example aspect 15: The apparatus of any one of the preceding example aspects, wherein:
the first hybrid is configured to couple a signal, a first signal component, and a second signal component;
the signal has a phase;
the first signal component has a first phase;
the second signal component has a second phase; and
the first phase and the second phase are each substantially different from the phase.

Example aspect 16: The apparatus of example aspect 15, wherein:
the second hybrid is configured to couple a signal, a first signal component, and a second signal component;
the signal of the second hybrid has a phase;
the first signal component of the second hybrid has a first phase;
the second signal component of the second hybrid has a second phase; and
the first phase and the second phase of the second hybrid are each substantially different from the phase of the second hybrid by an amount that is approximately equivalent to how much the first phase and the second phase of the first hybrid are each substantially different from the phase of the first hybrid.

Example aspect 17: The apparatus of example aspect 15 or 16, wherein the first phase and the second phase are each different from the phase by at least five degrees (5°).

Example aspect 18: The apparatus of any one of example aspects 15-17, wherein the first phase and the second phase are separate from each other by approximately ninety degrees (90°).

Example aspect 19: The apparatus of any one of example aspects 15-18, wherein:
the at least one duplexer circuit arrangement further comprises:
   a first capacitor; and
   a second capacitor;
the first hybrid comprises a first hybrid port, a second hybrid port, a third hybrid port, and a fourth hybrid port;
the first hybrid port is coupled to the first duplexer;
the second hybrid port is coupled to the second duplexer;
the third hybrid port is coupled to the first port;
the first capacitor is coupled between the first hybrid port and the third hybrid port; and
the second capacitor is coupled between the second hybrid port and the fourth hybrid port.

Example aspect 20: The apparatus of any one of the preceding example aspects, wherein the first hybrid and the second hybrid are configured to operate with a global phase offset.

Example aspect 21: The apparatus of any one of the preceding example aspects, further comprising:
an acoustic filter die comprising at least one acoustic filter, the first duplexer comprising the at least one acoustic filter; and
a load coupled to the first hybrid, the load comprising a resistor incorporated into the acoustic filter die.

Example aspect 22: The apparatus of example aspect 21, wherein the resistor comprises a meandered line disposed at least one of in or on a laminate of the acoustic filter die.

Example aspect 23: The apparatus of example aspect 21 or 22, wherein the load comprises a capacitor coupled in parallel with the resistor.

Example aspect 24: The apparatus of any one of the preceding example aspects, further comprising:
a radio-frequency front-end comprising the at least one duplexer circuit arrangement.

Example aspect 25: The apparatus of example aspect 24, further comprising:
a wireless interface device comprising the radio-frequency front-end;
a display screen; and
at least one processor operatively coupled to the display screen and at least a portion of the wireless interface device, the at least one processor configured to present one or more graphical images on the display screen based on one or more wireless signals communicated using the at least one duplexer circuit arrangement of the wireless interface device.

Example aspect 26: An apparatus comprising:
at least one duplexer circuit arrangement comprising:
   a first port, a second port, and a third port;
   a first duplexer and a second duplexer;
   first means for coupling the first port to the first duplexer and the second duplexer;
   second means for coupling the second port to the second duplexer and the first duplexer; and
   means for splitting and phase shifting at least one signal propagating between the third port and the first and second means for coupling.

Example aspect 27: The apparatus of example aspect 26, wherein the means for splitting and phase shifting at least one signal comprises:
means for phase shifting and combining at least one signal component.

Example aspect 28: A method of processing at least one signal with at least two duplexers, the method comprising:
splitting a reception signal into a first reception signal component and a second reception signal component;
shifting a phase of the first reception signal component responsive to propagating the first reception signal component along a first path to produce a first phase-shifted reception signal component;
shifting a phase of the second reception signal component responsive to propagating the second reception signal component along a second path to produce a second phase-shifted reception signal component;
filtering the first phase-shifted reception signal component using a first duplexer to produce a first filtered reception signal component;
filtering the second phase-shifted reception signal component using a second duplexer to produce a second filtered reception signal component; and
joining the first filtered reception signal component and the second filtered reception signal component to produce a combined reception signal.

Example aspect 29: The method of example aspect 28, further comprising:
separating a transmission signal into a first transmission signal component and a second transmission signal component, the first transmission signal component and the second transmission signal component having different phases;
filtering the first transmission signal component using the first duplexer to produce a first filtered transmission signal component;
filtering the second transmission signal component using the second duplexer to produce a second filtered transmission signal component;
shifting a phase of the first filtered transmission signal component responsive to propagating the first filtered transmission signal component along the first path to produce a first phase-shifted transmission signal component;
shifting a phase of the second filtered transmission signal component responsive to propagating the second filtered transmission signal component along the second path to produce a second phase-shifted transmission signal component; and
combining the first phase-shifted transmission signal component and the second phase-shifted transmission signal component to produce a combined transmission signal.

Example aspect 30: An apparatus comprising:
at least one duplexer circuit arrangement comprising:
   a first port, a second port, and a third port;
   a first duplexer and a second duplexer;
   a first hybrid coupled between the first port and the first duplexer and between the first port and the second duplexer;
   a second hybrid coupled between the second port and the second duplexer and between the second port and the first duplexer;
   a first path coupled between the first duplexer and the third port, the first path comprising at least one capacitor; and
   a second path coupled between the second duplexer and the third port, the second path comprising at least one inductor.

### CONCLUSION

As used herein, the terms “couple,” “coupled,” or “coupling” refer to a relationship between two or more components that are in operative communication with each other to implement some feature or realize some capability that is described herein. The coupling can be realized using, for instance, a physical line, such as a metal trace or wire, or an electromagnetic coupling, such as with a transformer. A coupling can include a direct coupling or an indirect coupling. A direct coupling refers to connecting discrete circuit elements via a same node without an intervening element. An indirect coupling refers to connecting discrete circuit elements via one or more other devices or other discrete circuit elements, including two or more different nodes.

The term “port” (e.g., including a “first port” or a “hybrid port”) represents at least a point of electrical connection at or proximate to the input or output of a component or between two or more components (e.g., active or passive circuit elements or parts). Although at times a port may be visually depicted in a drawing as a single point (or a circle), the port can represent an inter-connected portion of a physical circuit or network that has at least approximately a same voltage potential at or along the portion. In other words, a single-ended port can represent at least one point (e.g., a node) of multiple points along a conducting medium (e.g., a wire or trace) that exists between electrically connected components. In some cases, a “port” can represent at least one node that represents or corresponds to an input or an output of a component, such as a duplexer circuit arrangement or part thereof. Similarly, a “terminal” or a “node” may represent one or more points with at least approximately a same voltage potential relative to an input or output of a component.

The terms “first,” “second,” “third,” and other numeric-related indicators are used herein to identify or distinguish similar or analogous items from one another within a given context—such as a particular implementation, a single drawing figure, a given component, or a claim. Thus, a first item in one context may differ from a first item in another context. For example, an item identified as a “first duplexer” in one context may be identified as a “second duplexer” in another context. Similarly, a “first signal phase shifter” or a “first port” in one claim may be recited as a “second signal phase shifter” or a “third port,” respectively, in a different claim.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

Although implementations for realizing a duplexer circuit arrangement have been described in language specific to certain features and/or methods, the subject of the appended claims is not necessarily limited to the specific features or methods described. Rather, the specific features and methods are disclosed as example implementations for realizing a duplexer circuit arrangement.

What is claimed is:

1. An apparatus comprising:
at least one duplexer circuit arrangement comprising:
a first port, a second port, and a third port;
a first duplexer and a second duplexer;
a first hybrid coupled between the first port and the first duplexer and between the first port and the second duplexer;
a second hybrid coupled between the second port and the second duplexer and between the second port and the first duplexer; and
a splitter and phase shifter circuit coupled between the third port and the first and second duplexers.

2. The apparatus of claim 1, wherein:
the splitter and phase shifter circuit comprises a first path and a second path; and
the splitter and phase shifter circuit is configured to shift a relative phase between a first signal propagating on the first path and a second signal propagating on the second path.

3. The apparatus of claim 1, wherein:
the first port is configured to be coupled to an output of a power amplifier;
the second port is configured to be coupled to an input of a low-noise amplifier; and
the third port is configured to be coupled to an antenna.

4. The apparatus of claim 1, wherein the splitter and phase shifter circuit comprises:
a signal splitter coupled to the third port;
a first path coupled between the signal splitter and the first duplexer;
a second path coupled between the signal splitter and the second duplexer; and
at least one signal phase shifter coupled along at least one of the first path or the second path.

5. The apparatus of claim 4, wherein:
the at least one signal phase shifter comprises a first signal phase shifter and a second signal phase shifter;
the first path comprises the first signal phase shifter; and
the second path comprises the second signal phase shifter.

6. The apparatus of claim 1, wherein:
the at least one duplexer circuit arrangement further comprises:
a load;
a first capacitor; and
a second capacitor;
the first hybrid comprises a first hybrid port, a second hybrid port, a third hybrid port, and a fourth hybrid port;
the first hybrid port is coupled to the first duplexer;
the second hybrid port is coupled to the second duplexer;
the third hybrid port is coupled to the first port;
the fourth hybrid port is coupled to the load;
the first capacitor is coupled between the first hybrid port and the fourth hybrid port; and
the second capacitor is coupled between the second hybrid port and the third hybrid port.

7. The apparatus of claim 6, wherein:
the at least one duplexer circuit arrangement further comprises:
a third capacitor; and
a fourth capacitor;
the third capacitor is coupled between the first hybrid port and the third hybrid port; and
the fourth capacitor is coupled between the second hybrid port and the fourth hybrid port.

8. The apparatus of claim 1, wherein:
the at least one duplexer circuit arrangement further comprises:
a load;
a first capacitor; and
a second capacitor;
the first hybrid comprises a first hybrid port, a second hybrid port, a third hybrid port, and a fourth hybrid port;
the first hybrid port is coupled to the first duplexer;
the second hybrid port is coupled to the second duplexer;
the third hybrid port is coupled to the first port;
the fourth hybrid port is coupled to the load;
the first capacitor is coupled between the first hybrid port and the third hybrid port; and
the second capacitor is coupled between the second hybrid port and the fourth hybrid port.

9. The apparatus of claim 1, wherein:
the first hybrid is configured to couple a signal, a first signal component, and a second signal component;
the signal has a phase;
the first signal component has a first phase;
the second signal component has a second phase; and
the first phase and the second phase are each substantially different from the phase.

10. The apparatus of claim 9, wherein:
the second hybrid is configured to couple a signal, a first signal component, and a second signal component;
the signal of the second hybrid has a phase;
the first signal component of the second hybrid has a first phase;
the second signal component of the second hybrid has a second phase; and
the first phase and the second phase of the second hybrid are each substantially different from the phase of the second hybrid by an amount that is approximately equivalent to how much the first phase and the second phase of the first hybrid are each substantially different from the phase of the first hybrid.

11. The apparatus of claim 9, wherein:
the at least one duplexer circuit arrangement further comprises:
a first capacitor; and
a second capacitor;
the first hybrid comprises a first hybrid port, a second hybrid port, a third hybrid port, and a fourth hybrid port;
the first hybrid port is coupled to the first duplexer;
the second hybrid port is coupled to the second duplexer;
the third hybrid port is coupled to the first port;
the first capacitor is coupled between the first hybrid port and the third hybrid port; and
the second capacitor is coupled between the second hybrid port and the fourth hybrid port.

12. The apparatus of claim 1, wherein the first hybrid and the second hybrid are configured to operate with a global phase offset.

13. The apparatus of claim 1, further comprising:
an acoustic filter die comprising at least one acoustic filter, the first duplexer comprising the at least one acoustic filter; and
a load coupled to the first hybrid, the load comprising a resistor incorporated into the acoustic filter die.

14. The apparatus of claim 13, wherein the resistor comprises a meandered line disposed at least one of in or on a laminate of the acoustic filter die.

15. The apparatus of claim 13, wherein the load comprises a capacitor coupled in parallel with the resistor.

16. The apparatus of claim 1, further comprising:
a radio-frequency front-end comprising the at least one duplexer circuit arrangement.

17. An apparatus comprising:
at least one duplexer circuit arrangement comprising:
a first port, a second port, and a third port;
a first duplexer and a second duplexer;
first means for coupling the first port to the first duplexer and the second duplexer;
second means for coupling the second port to the second duplexer and the first duplexer; and
means for splitting and phase shifting at least one signal propagating between the third port and the first and second means for coupling.

18. The apparatus of claim 17, wherein the means for splitting and phase shifting at least one signal comprises:
means for phase shifting and combining at least one signal component.

19. A method of processing at least one signal with at least two duplexers, the method comprising:
splitting a reception signal into a first reception signal component and a second reception signal component;
shifting a phase of the first reception signal component responsive to propagating the first reception signal component along a first path to produce a first phase-shifted reception signal component;
shifting a phase of the second reception signal component responsive to propagating the second reception signal component along a second path to produce a second phase-shifted reception signal component;
filtering the first phase-shifted reception signal component using a first duplexer to produce a first filtered reception signal component;
filtering the second phase-shifted reception signal component using a second duplexer to produce a second filtered reception signal component; and
joining the first filtered reception signal component and the second filtered reception signal component to produce a combined reception signal.

20. The method of claim 19, further comprising:
separating a transmission signal into a first transmission signal component and a second transmission signal component, the first transmission signal component and the second transmission signal component having different phases;
filtering the first transmission signal component using the first duplexer to produce a first filtered transmission signal component;
filtering the second transmission signal component using the second duplexer to produce a second filtered transmission signal component;
shifting a phase of the first filtered transmission signal component responsive to propagating the first filtered transmission signal component along the first path to produce a first phase-shifted transmission signal component;
shifting a phase of the second filtered transmission signal component responsive to propagating the second filtered transmission signal component along the second path to produce a second phase-shifted transmission signal component; and
combining the first phase-shifted transmission signal component and the second phase-shifted transmission signal component to produce a combined transmission signal.
